(19) United States
(12) Patent Application Publication
(10) Pub. No.: US 2016/0148861 A1
(43) Pub. Date: May 26, 2016

(54) FIRST-PACKAGED AND LATER-ETCHED THREE-DIMENSIONAL FLIP-CHIP SYSTEM-IN-PACKAGE STRUCTURE AND PROCESSING METHOD THEREFOR

(71) Applicant: JIANGSU CHANGJIANG ELECTRONICS TECHNOLOGY CO., LTD, Jiangsu (CN)

(72) Inventors: Chih-Chung Liang, Jiangsu (CN); Steve Xin Liang, Jiangsu (CN); Yu-bin Lin, Jiangsu (CN); Kai Zhang, Jiangsu (CN); Chunyan Zhang, Jiangsu (CN)

(21) Appl. No.: 14/901,526

(22) PCT Filed: Dec. 19, 2013
(86) PCT No.: PCT/CN2013/001604

§ 371 Date: Dec. 28, 2015

(30) Foreign Application Priority Data
Aug. 6, 2013 (CN) 201310340789.0

(51) Int. Cl. H01L 23/495; H01L 23/00; H01L 21/78; H01L 21/304; H01L 21/306; H01L 23/29; H01L 21/027; H01L 21/56

(52) U.S. Cl. CPC H01L 23/49575; H01L 21/0274; H01L 24/83; H01L 24/05; H01L 24/03; H01L 21/565; H01L 21/304; H01L 21/30604; H01L 23/49558; H01L 23/293; H01L 21/78; H01L 2224/83447; H01L 2224/04042; H01L 2224/3223

(57) ABSTRACT

A first-packaged and later-etched three-dimensional flip-chip system-in-package structure and a processing method thereof are provided. The package structure includes: a pad (1), a pin (2); a conductive pillar (3) disposed on an upper surface of the pin (2); a first die (4) flipped on an upper surface of the pad (1); a first molding material or epoxy resin (9) for encapsulating with a peripheral region of the conductive pillar (3) and the first die (4); an anti-oxidation layer (11) provided on a surface of the conductive pillar (3) exposed from the first molding material or epoxy resin (9); a second die (8) flipped on a lower surface of the pad (1) and the pin (2); and a second molding material or epoxy resin (10) for encapsulating with the region of the lower surfaces of the pad (1) and the pin (2) and a peripheral region of the second die (8). With the first-packaged and later-etched three-dimensional system-in-package flip-chip package structure and the processing method thereof, the following problem is solved: a function integration level of the whole package is limited because no object can be embedded into a conventional metal lead frame and an organic substrate, and a narrower width and a narrower pitch between lines is necessary for a conventional organic substrate.

This application claims the priority to Chinese Patent Application No. 201310340789.0, entitled “FIRST-PACKAGED AND LATER-ETCHED THREE-DIMENSIONAL FLIP-CHIP SYSTEM-IN-PACKAGE STRUCTURE AND PROCESSING METHOD THEREFOR”, filed with the Chinese Patent Office on Aug. 6, 2013, which is incorporated by reference in its entirety herein.

### BACKGROUND

A conventional quad no-lead metal lead package structure is shown in FIG. 98. A processing of manufacturing the metal lead package structure may include: performing a chemical etching and metal plating on a metal sheet to obtain a metal lead frame having pads for carrying chips, and inner and outer pins, and then performing a packaging process such as unilateral die bonding, wire bonding and encapsulating on the metal lead frame.

FIG. 99 shows a conventional organic multiple-layer wiring substrate package structure. A processing of manufacturing the organic multiple-layer wiring substrate package structure may include: stacking a deposited material on a core material of a glass fiber plate in a deposited manner to form a multiple-layer wiring substrate, forming through-holes via the wiring layers by a laser drilling, plating the through-holes to achieve an electric connection, and then performing a packaging process such as unilateral die bonding, wire bonding and encapsulating on the multiple-layer wiring substrate.

Both of the metal lead frame package structure and the multiple-layer wiring substrate package structure have the following disadvantages.

1. Only unilateral chip packaging can be performed on this type of metal lead frame and multiple-layer wiring substrate, thus the metal lead frame or multiple-layer wiring substrate have a low utilization, and a function integration level of whole package is limited.

2. No object is embedded into this type of metal lead frame and multiple-layer wiring substrate, thus the metal lead frame and multiple-layer wiring substrate has no functional integration effect, and a function integration level of the whole package is limited.

3. The organic multiple-layer substrate has high material cost and high manufacturing cost.

4. The conventional metal lead frame has great wire width and wire pitch, which is equal to or larger than 200 μm, and thereby the high-density requirement can not be met.

5. The conventional organic multiple-layer wiring has a wire width of larger than 25 μm and a wire pitch of larger than 25 μm depending on the current etching processing, which are slightly wider in practice.

### SUMMARY

An object of present disclosure is to overcome the disadvantages described above. A first-packaged and later-etched flip-chip three-dimensional system-in-package structure and a processing method thereof are provided. The following problems may be solved: the function integration level of the whole package is limited because a chip and a passive component cannot be embedded into a conventional metal lead frame or a multiple-layer wiring substrate; and compared with the conventional organic substrate, lines with a narrower width and a finer pitch are necessary.

The object of the present disclosure may be achieved as follows. A processing method for first-packaged and later-etched a three-dimensional flip-chip system-in-package structure is provided, which includes:

step 1, preparing a metal substrate;

step 2, pre-plating surfaces of the metal substrate with a copper material,

wherein the surfaces of the metal substrate are pre-plated with a layer of copper material;

step 3, applying a photoresist film,

wherein the photoresist film for exposing and developing is applied on an upper surface and a lower surface of the metal substrate pre-plated with the copper material in step 2;

step 4, removing a part of the photoresist film on the upper surface of the metal substrate,

wherein the upper surface of the metal substrate applied with the photoresist film in step 3 is exposed and developed in a pattern by an exposure and development device, to remove the part of the photoresist film in the pattern and expose a region of the upper surface of the metal substrate to be plated with a metal wiring layer;

step 5, plating with the metal wiring layer,

wherein the region of the upper surface of the metal substrate, on which the part of the photoresist film is removed in step 4, is plated with the metal wiring layer to form pads and pins on the upper surface of the metal substrate;

step 6, applying a photoresist film,

wherein the photoresist film for exposing and developing is applied on the upper surface of the metal substrate plated with the metal wiring layer in step 5;

step 7, removing a part of the photoresist film on the upper surface of the metal substrate,

wherein the upper surface of the metal substrate applied with the photoresist film in step 6 is exposed and developed in a pattern by an exposure and development device, to remove the part of the photoresist film in the pattern and expose a region of the upper surface of the metal substrate to be plated with a conductive pillars;

step 8, plating with the conductive pillars,

wherein the region of the upper surface of the metal substrate, on which the part of the photoresist film has been removed in step 7, is plated with the conductive pillars;

step 9, removing the photoresist film,

wherein the photoresist film on the surface of the metal substrate is removed;

step 10, bonding dies,

wherein a conductive or non-conductive adhesive material is applied on upper surfaces of the pads formed in step 5 to bond first dies;

step 11, bonding metal wires,

wherein the metal wire is bonded between an upper surface of the first die and the pin formed in step 5;

step 12, molding with an epoxy resin,

wherein the upper surface of the metal substrate bonded with the die and the metal wires is molded with the epoxy resin to protect the upper surface of the metal substrate;

step 13, grinding a surface of the epoxy resin,

wherein the surface of the epoxy resin is ground after the epoxy resin is molded in step 12;

step 14, applying a photoresist film,

wherein the photoresist film for exposing and developing is applied on the upper surface and the lower surface of the metal substrate after the surface of the epoxy resin is ground in step 13;

step 15, removing a part of the photoresist film on the lower surface of the metal substrate,

wherein the lower surface of the metal substrate applied with the photoresist film in step 14 is exposed and developed in a pattern by an exposure and development device to remove the part of the photoresist film in the pattern and expose a region of the lower surface of the metal substrate to be etched;

step 16, etching;

wherein a chemical etching is performed on the region of the lower surface of the metal substrate, on which the part of the photoresist film is removed in step 15;

step 17, removing the photoresist film,

wherein the photoresist film on the surface of the metal substrate is removed by softening the photoresist film with a chemical regent or cleaning the surface of the metal substrate with high pressure water;

step 18, plating with an anti-oxidizing metal layer or coating with an antioxidant,

wherein the exposed surface of the metal substrate, on which the photoresist film is removed in step 17, is plated with the anti-oxidizing metal layer or is coated with the antioxidant;

step 19, flipping chip;

wherein second dies are flipped, via a metal ball, on a lower surface off the pads and the pins, which are plated with the anti-oxidizing metal layer or the coated with the antioxidant, and gaps between metal balls, between the die and the pad, and between the pins are filled with an underfill;

step 20, molding with an epoxy resin,

wherein the lower surface of the metal substrate bonded with the dies is molded with the epoxy resin to protect the lower surface of the metal substrate; and step 21, package sawing to form a finished product,

wherein a semi-finished product is sawed after the epoxy resin is molded in step 20; and molded body modules of the metal wiring substrate, which are integrated initially in an array aggregate and contain dies, are sawed to be separated from one another, to form the finished product of a first-packaged and later-etched three-dimensional flip-chip system-in-package structure.

A processing method for first-packaged and later-etched a three-dimensional flip-chip system-in-package structure is provided, which includes:

step 1, preparing a metal substrate;

step 2, pre-plating surfaces of the metal substrate with a copper material,

wherein the surfaces of the metal substrate are pre-plated with a layer of copper material;

step 3, applying a photoresist film,

wherein the photoresist film for exposing and developing is applied on an upper surface and a lower surface of the metal substrate pre-plated with the copper material in step 2;

step 4, removing a part of the photoresist film on the upper surface of the metal substrate,

wherein the upper surface of the metal substrate applied with the photoresist film in step 3 is exposed and developed in a pattern by an exposure and development device to remove the part of the photoresist film in the pattern and expose a region of the upper surface of the metal substrate to be plated with a metal wiring layer;

step 5, plating with the metal wiring layer,

wherein the region of the upper surface of the metal substrate, on which the part of the photoresist film is removed in step 4, is plated with the metal wiring layer to form pads and pins on the upper surface of the metal substrate;

step 6, applying a photoresist film,

wherein the photoresist film for exposing and developing is applied on the upper surface of the metal substrate plated with the metal wiring layer in step 5;

step 7, removing a part of the photoresist film on the upper surface of the metal substrate,

wherein the upper surface of the metal substrate applied with the photoresist film in step 6 is exposed and developed in a pattern by an exposure and development device, to remove the part of the photoresist film in the pattern and expose a region of the upper surface of the metal substrate to be plated with conductive pillars;

step 8, plating with the conductive pillars,

wherein the region of the upper surface of the metal substrate, on which the part of the photoresist film has been removed in step 7, is plated with the conductive pillars;

step 9, removing the photoresist film,

wherein the photoresist film on the surface of the metal substrate is removed;

step 10, bonding dies,

wherein a conductive or non-conductive adhesive material is applied on upper surfaces of the pads formed in step 5 to bond first dies;

step 11, bonding metal wires,

wherein the metal wires are bonded between an upper surface of the first die and the pin formed in step 5;

step 12, molding with an epoxy resin,

wherein the upper surface of the metal substrate bonded with the die and the metal wires is molded with the epoxy resin to protect the upper surface of the metal substrate;

step 13, grinding a surface of the epoxy resin,

wherein the surface of the epoxy resin is ground after the epoxy resin is molded in step 12;

step 14, applying a photoresist film,

wherein the photoresist film for exposing and developing is applied on the upper surface and the lower surface of the metal substrate after the surface of the epoxy resin has been ground in step 13;

step 15, removing a part of the photoresist film on the lower surface of the metal substrate,

wherein the lower surface of the metal substrate applied with the photoresist film in step 14 is exposed and developed in a pattern by an exposure and development device to remove the part of the photoresist film in the pattern and expose a region of the lower surface of the metal substrate to be etched;

step 16, etching;

wherein a chemical etching is performed on the region of the lower surface of the metal substrate, on which the part of the photoresist film is removed in step 15;

step 17, removing the photoresist film,

wherein the photoresist film on the surface of the metal substrate is removed;

step 18, coating the lower surface of the metal substrate with a solder mask or a sensitive non-conductive adhesive material,

wherein the lower surface of the metal substrate is coated with the solder mask or the sensitive non-conductive adhesive material after the photoresist film is removed in step 17;

step 19, exposing and developing to form a window;

wherein the solder mask or the sensitive non-conductive adhesive material on the lower surface of the metal substrate is exposed and developed by an exposure and development device to form the window and expose a region of the lower surface of the metal substrate to be plated with a high conductivity metal layer;

step 20, plating with the high conductivity metal layer,

wherein a region of the window of the solder mask or the sensitive non-conductive adhesive material in step 19 on the lower surface of the metal substrate is plated with the high conductivity metal layer;

step 21, plating with an anti-oxidizing metal layer or coating with an antioxidant,

wherein the exposed surface of the metal substrate is plated with the anti-oxidizing metal layer or is coated with the antioxidant;

step 22, flipping chips;

wherein second dies are flipped, via second metal balls, on tops of the conductive pillars plated with the anti-oxidizing metal layer or coated with the antioxidant in step 21; and gaps between metal balls, and between the die and the conductive pillar may also be filled with an underfill;

step 23, molding with an epoxy resin,

wherein the surface of epoxy resin bonded with the die is molded with the epoxy resin; and

step 24, package sawing to form a finished product,

wherein a semi-finished product is sawed after the epoxy resin is molded in step 23, and molded body modules of the metal wiring substrate, which are integrated initially in array aggregate and contain dies, are sawed to be separated from one another, to form the finished product of a first-packaged and later-etched three-dimensional flip-chip system-in-package structure.

A processing method for first-packaged and later-etched a three-dimensional flip-chip system-in-package structure is provided, which includes:

step 1, preparing a metal substrate;

step 2, pre-plating surfaces of the metal substrate with a copper material,

wherein the surfaces of the metal substrate are pre-plated with a layer of copper material;

step 3, applying a photoresist film,

wherein the photoresist film for exposing and developing is applied on an upper surface and a lower surface of the metal substrate pre-plated with the copper material in step 2;

step 4, removing a part of the photoresist film on the upper surface of the metal substrate,

wherein the upper surface of the metal substrate applied with the photoresist film in step 3 is exposed and developed in a pattern by an exposure and development device to remove the part of the photoresist film in the pattern and expose a region of the upper surface of the metal substrate to be plated with a first metal wiring layer;

step 5, plating with the first metal wiring layer,

wherein the region of the upper surface of the metal substrate, on which the part of the photoresist film is removed in step 4, is plated with the first metal wiring layer;

step 6, applying a photoresist film,

wherein the photoresist film for exposing and developing is applied on the upper surface of the metal substrate plated with the first metal wiring layer in step 5;

step 7, removing a part of the photoresist film on the upper surface of the metal substrate,

wherein the upper surface of the metal substrate applied with the photoresist film in step 6 is exposed and developed in a pattern by an exposure and development device to remove the part of the photoresist film in the pattern and expose a region of the upper surface of the metal substrate to be plated with a second metal wiring layer;

step 8, plating with the second metal wiring layer,

wherein the region of the upper surface of the metal substrate, on which the part of the photoresist film is removed in step 7, is plated with the second metal wiring layer, and the second metal wiring layer serves as a conductive pillar to connect the first metal wiring layer and a third metal wiring layer;

step 9, removing the photoresist film,

wherein the photoresist film on the surface of the metal substrate is removed;

step 10, laminating with a non-conductive adhesive film,

wherein a layer of the non-conductive adhesive film is laminated on the upper surface of the metal substrate;

step 11, grinding a surface of the non-conductive adhesive film,

wherein the surface of the non-conductive adhesive film is ground after the non-conductive adhesive film is laminated in step 10;

step 12, performing a metallization pretreatment on the surface of the non-conductive adhesive film,

wherein the metallization pretreatment is performed on the surface of the non-conductive adhesive film to adhere a layer of metallized polymer material onto the surface of the non-conductive adhesive film, or a surface roughening treatment is performed on the surface of the non-conductive adhesive film;

step 13, applying a photoresist film,

wherein the photoresist film for exposing and developing is applied on the upper surface and the lower surface of the metal substrate on which the metallization pretreatment is performed in step 12;

step 14, removing a part of the photoresist film on the upper surface of the metal substrate,

wherein the upper surface of the metal substrate applied with the photoresist film in step 13 is exposed and developed in a pattern by an exposure and development device, to remove the part of the photoresist film in the pattern and expose a region of the upper surface of the metal substrate to be etched;

step 15, etching;

wherein the etching is performed on a region of the upper surface of the metal substrate on which the part of the photoresist film is removed in step 14;

step 16, removing the photoresist film,

wherein the photoresist film on the surface of the metal substrate is removed;

step 17, plating with a third metal wiring layer,

wherein a metallization pretreatment region of the upper surface of the metal substrate reserved by the etching in step 15 is plated with the third metal wiring layer to form a pad and pins on the upper surface of the metal substrate;

step 18, applying a photoresist film,

wherein the photoresist film for exposing and developing is applied on the upper surface of the metal substrate plated with the third metal wiring layer in step 17;

step 19, removing a part of the photoresist film on the upper surface of the metal substrate,

wherein the upper surface of the metal substrate applied with the photoresist film in step 18 is exposed and developed in a pattern by an exposure and development device to remove the part of the photoresist film in the pattern and expose a region of the upper surface of the metal substrate to be plated with conductive pillars;

step 20, plating with the conductive pillars,

wherein the region of the upper surface of the metal substrate, on which the part of the photoresist film has been removed in step 19, is plated with the conductive pillars;

step 21, removing the photoresist film,

wherein the photoresist film on the surface of the metal substrate is removed;

step 22, bonding dies,

wherein a conductive or non-conductive adhesive material is applied on upper surfaces of the pads formed in step 17 to bond first dies;

step 23, bonding metal wires,

wherein the metal wire is bonded between an upper surface of the first die and the pin formed in step 17;

step 24, molding with an epoxy resin,

wherein the upper surface of the metal substrate bonded with the die and the metal wires is molded with the epoxy resin to protect the upper surface of the metal substrate;

step 25, grinding a surface of the epoxy resin,

wherein the surface of the epoxy resin is ground after the epoxy resin is molded in step 24;

step 26, applying a photoresist film,

wherein the photoresist film for exposing and developing is applied on the upper surface and the lower surface of the metal substrate after the surface of the epoxy resin is ground in step 25;

step 27, removing a part of the photoresist film on the lower surface of the metal substrate,

wherein the lower surface of the metal substrate applied with the photoresist film in step 26 is exposed and developed in a pattern by an exposure and development device to remove the part of the photoresist film in the pattern and expose a region of the lower surface of the metal substrate to be etched;

step 28, etching;

wherein a chemical etching is performed on the region of the lower surface of the metal substrate, on which the part of the photoresist film is removed in step 27;

step 29, removing the photoresist film,

wherein the photoresist film on the surface of the metal substrate is removed;

step 30, plating with an anti-oxidizing metal layer or coating with an antioxidant,

wherein the exposed surface of the metal substrate, on which the photoresist film has been removed in step 29, is plated with the anti-oxidizing metal layer or is coated with the antioxidant;

step 31, flipping chips;

wherein second dies are flipped on a lower surface of the lower surfaces of the pad and the pin plated with the anti-oxidizing metal layer or coated with the antioxidant in step 30, by filling gaps between metal balls, between the die and the pad, and between the dies with an underfill;

step 32, molding with an epoxy resin,

wherein the lower surface of the metal substrate bonded with the die is molded with the epoxy resin to protect the lower surface of the metal substrate; and step 33, package sawing to form a finished product,

wherein a semi-finished product is sawed after the epoxy resin is molded in step 32; and molded body modules of the metal wire substrate, which are integrated initially in array aggregate and contain dies, are sawed to be separated from one another, to form the finished product of a first-packaged and later-etched three-dimensional flip-chip system-in-package structure.

Alternatively, during step 5 to step 17 are performed, step 8 to step 18 are performed repeatedly.

A first-packaged and later-etched three-dimensional flip-chip system-in-package structure is provided, which includes: a pad; a pin; a conductive pillar disposed on an upper surface of the pin; a first die flipped on an upper surface of the pad by a conductive or non-conductive adhesive material; a first metal wire for connecting an upper surface of the first die to the upper surface of the pin; a first molding material or epoxy resin for encapsulating with regions of the upper surfaces of the pad and the pin, and a peripheral region of the conductive pillar, the first die and the first metal wires, with a top of the first molding material or epoxy resin being flush with a top of the conductive pillar; an anti-oxidation layer provided on a surface of the conductive pillar exposed from the first molding material or epoxy resin; a second die flipped on lower surfaces of the pad and the pin by an underfill; and a second molding material or epoxy resin for encapsulating with the region of the lower surfaces of the pad and the pin and a peripheral region of the second die.

Alternatively, a passive device may be connected across the pins.

Alternatively, a plurality of second dies may be flipped on the lower surfaces of the pad and the pin by filling gaps between metal balls, between the chip and the pad, and between the chips with an underfill.

Alternatively, a third die may be flipped on the lower surface of the second die by the conductive or non-conductive adhesive material, and the third die is connected to the lower surface of the pin via a second metal wire.

Alternatively, a third die may be flipped on lower surfaces of the pin via a second metal ball, and the second metal ball and the third die are located within the molding material.

Alternatively, the third die may be replaced by a passive device, and the second metal ball and the passive device are located within the molding material.

A first-packaged and later-etched three-dimensional flip-chip system-in-package structure is provided, which includes: a pad; a pin; a conductive pillar disposed on an upper surface of the pin; a first die flipped on an upper surface of the pad by a conductive or non-conductive adhesive material; a first metal wire for connecting an upper surface of the first die to the upper surface of the pin; a first molding material or epoxy resin for encapsulating with regions of the upper surfaces of the pad and the pin, and a peripheral region of the conductive pillar, the first die and the first metal wire, with a top of the first molding material or epoxy resin being flush with a top of the conductive pillar; a second die flipped on the top of the conductive pillar via first metal balls; and a second molding material or epoxy resin for encapsulating with a top region of the conductive pillar and a peripheral region of the second die; high conductivity metal layers provided on lower surfaces of the pad and the pin; a solder mask or sensitive non-conductive adhesive material filled between the high conductivity metal layers; and an anti-oxidation layer provided on surfaces of the high conductivity metal layers exposed from the solder mask or sensitive non-conductive adhesive material.

As compared with the prior art, the present disclosure has the following beneficial effects.

1. At present, no object can be embedded into the metal lead frame and organic multiple-layer wiring substrate, thus a function integration level of the whole package is limited. In the three-dimensional system-in-package metal wiring substrate provided in the present disclosure, an object can be embedded into an interlayer between the substrates in the manufacturing process, thus chips and other assemblies may be carried on both sides of the three-dimensional system-in-package metal wiring substrate, and the function integration level of the whole package is improved.

2. A heat conductive or a heat diffusion object can be embedded into a position or region of the interlayer of the three-dimensional system-in-package metal wiring substrate in the manufacturing process as required, and thus the effect of the heat diffusion of the whole package structure is improved.

3. An active element, assembly or passive assembly can be embedded into a position or region of the interlayer of the three-dimensional system-in-package metal wiring substrate in the manufacturing process as required by the system or function, and thus the utilization of substrate is improved.

4. The object, which is necessary for system or function and has been embedded into the interlayer, cannot be found from the appearance of the three-dimensional system-in-package metal wiring substrate package finished product. Particularly, the embedding of the silicon chip cannot even be detected by X ray, and thereby the secrecy and protectiveness of the system and function can be achieved fully.

5. The three-dimensional system-in-package metal wiring substrate may integrate with many system functions, thus the space of PCB occupied by the elements with the same function is smaller and the cost is lowered.

6. A high voltage device can be embedded into the interlayer of three-dimensional system-in-package metal wiring substrate in the manufacturing process, the high voltage device and the control chip are respectively provided on two sides of the substrate, thus avoiding the interference on the signal transmission due to the heat diffusion of the high voltage device.

7. The wiring of the three-dimensional system-in-package metal wiring substrate is manufactured by plating, and the wire width and wire pitch may be smaller than 15 μm.

8. The three-dimensional system-in-package metal wiring substrate is manufactured by plating, etching, and molding process, which has a simple process and a lower cost than that of the organic substrate by about 30%.

### BRIEF DESCRIPTION OF THE DRAWINGS

FIG. 1 to FIG. 21 are respectively a schematic procedure diagram of a processing method of a first-packaged and later-etched three-dimensional flip-chip system-in-package structure according to a first embodiment of the present disclosure;

FIG. 22 is a schematic diagram of the first-packaged and later-etched three-dimensional flip-chip system-in-package structure according to the first embodiment of the present disclosure;

FIG. 23 to FIG. 46 are respectively a schematic procedure diagram of a processing method of a first-packaged and later-etched three-dimensional flip-chip system-in-package structure according to a second embodiment of the present disclosure;

FIG. 47 is a schematic diagram of the first-packaged and later-etched three-dimensional flip-chip system-in-package structure according to the second embodiment of the present disclosure;

FIG. 48 to FIG. 92 are respectively a schematic procedure diagram of a processing method of a first-packaged and later-etched three-dimensional flip-chip system-in-package structure according to a third embodiment of the present disclosure;

FIG. 93 is a schematic diagram of the first-packaged and later-etched three-dimensional flip-chip system-in-package structure according to the third embodiment of the present disclosure;

FIG. 94 is a schematic diagram of a first-packaged and later-etched three-dimensional flip-chip system-in-package structure according to a fourth embodiment of the present disclosure;

FIG. 95 is a schematic diagram of a first-packaged and later-etched three-dimensional flip-chip system-in-package structure according to a fifth embodiment of the present disclosure;

FIG. 96 is a schematic diagram of a first-packaged and later-etched three-dimensional flip-chip system-in-package structure according to a sixth embodiment of the present disclosure;

FIG. 97 is a schematic diagram of a first-packaged and later-etched three-dimensional flip-chip system-in-package structure according to a seventh embodiment of the present disclosure;

FIG. 98 is a schematic diagram of a conventional quad no-lead metal lead package structure; and

FIG. 99 is a schematic diagram of a conventional organic multiple-layer wiring substrate package structure.

In the drawings:
pad 1
pin 2
conductive pillar 3
first die 4
first metal wire 5
conductive or non-conductive adhesive material 6
underfill 7
second die 8
first molding material or epoxy resin 9
second molding material or epoxy resin 10
anti-oxidation layer 11
high conductivity metal layer 12
solder mask or sensitive non-conductive adhesive material 13
passive device 14
third die 15
second metal wire 16
first metal ball 17
second metal ball 18

### DETAILED DESCRIPTION OF EMBODIMENTS

A processing method of a first-packaged and later-etched three-dimensional flip-chip system-in-package structure is provided in the present disclosure.

### First Embodiment

### Single-Layer Wiring, Single Flip-Chip, and Lap Lead (1)

Referring to FIG. 22, a first-packaged and later-etched three-dimensional flip-chip system-in-package structure is provided in the present disclosure, which includes: a pad 1; a pin 2; a conductive pillar 3 provided on an upper surface of the pin 2; a first die 4 flipped on an upper surface of the pad 1 by a conductive or non-conductive adhesive material 6; a first metal wire 5 for connecting an upper surface of the first die 4 to the upper surface of the pin 2; a first molding material or epoxy resin 9 for encapsulating with regions of the upper surface of the pad 1 and the pin 2, and a peripheral region of the conductive pillar 3, the first die 4 and the first metal wire 5, with a top of the first molding material or epoxy resin 9 being flush with a top of the conductive pillar 3; an anti-oxidation layer 11 provided on a surface of the conductive pillar 3 exposed from the first molding material or epoxy resin 9; a second die 8 flipped on lower surfaces of the pad 1 and the pin 2 by an underfill 7; and a second molding material or epoxy resin 10 for encapsulating with regions of the lower surfaces of the pad 1 and the pin 2, and a peripheral region of the second die 8.

The processing method of a first-packaged and later-etched three-dimensional flip-chip system-in-package structure includes the following steps 1 to 21.

Step 1, Preparing a Metal Substrate.

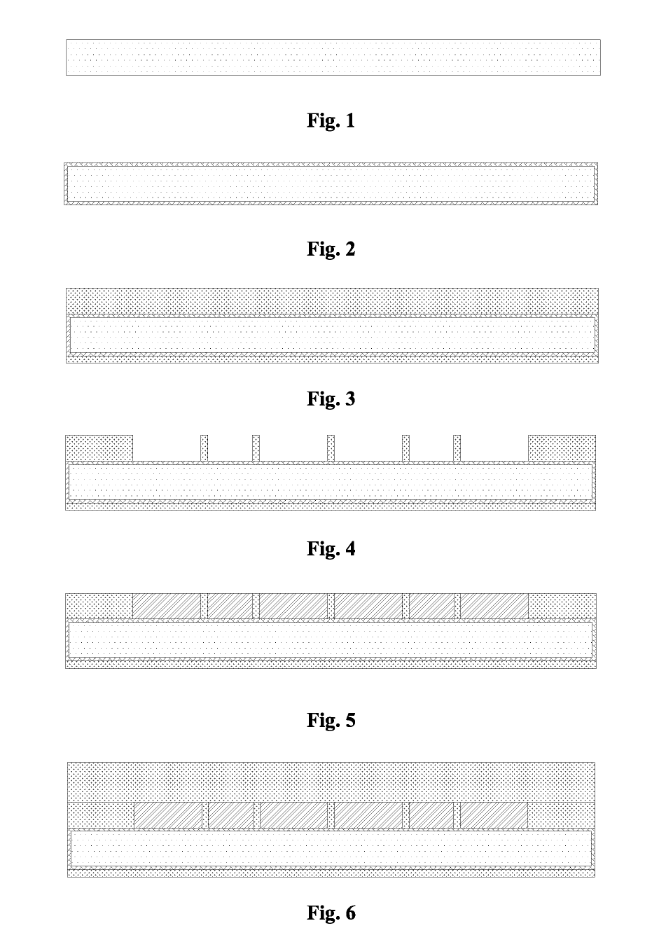

Referring to FIG. 1, the metal substrate of a suitable thickness is prepared. The metal substrate may be made from copper material, iron material, galvanized material, stainless steel, aluminum material, or metal or nonmetal material which may conduct the electricity. The thickness of the metal substrate may be selected according to the product characteristic.

Step 2, Pre-Plating Surfaces of the Metal Substrate with a Copper Material.

Referring to FIG. 2, the surfaces of the metal substrate are pre-plated with a layer of copper material. The copper layer has a thickness of 2 μm to 10 μm, which may also be thinned or thickened according to the function requirement. The plating may be electrolytic plating, and may also be achieved by chemical deposition.

Step 3, Applying a Photoresist Film.

Referring to FIG. 3, for manufacturing a metal wiring pattern on the metal substrate later, the photoresist film for exposing and developing is applied on an upper surface and a lower surface of the metal substrate pre-plated with the copper material in step 2. The photoresist film may be a dry photoresist film or a wet photoresist film.

Step 4, Removing a Part of the Photoresist Film on the Upper Surface of the Metal Substrate.

Referring to FIG. 4, the upper surface of the metal substrate applied with the photoresist film in step 3 is exposed and developed in a pattern by an exposure and development device, and the part of the photoresist film in the pattern is removed to expose a region of the upper surface of the metal substrate to be plated with a metal wiring layer.

Step 5, Plating with the Metal Wiring Layer.

Referring to FIG. 5, the region of the upper surface of the metal substrate, on which the part of the photoresist film has been removed in step 4, is plated with the metal wiring layer to form pads and pins on the upper surface of the metal substrate. The metal wiring layer may be made from copper, aluminum, nickel, silver, gold, copper-silver, nickel-gold, nickel-palladium-gold or the like. The metal wiring layer has a thickness of 5 μm to 20 μm. The material for plating may be selected depending on an actual application. The plated thickness can be changed according to product characteristic. The plating may be electrolytic plating or may be achieved by chemical deposition.

Step 6, Applying a Photoresist Film.

Referring to FIG. 6, for manufacturing conductive pillars later, the photoresist film for exposing and developing is applied on the upper surface of the metal substrate plated with the metal wiring layer in step 5. The photoresist film may be a dry photoresist film or a wet photoresist film.

Step 7, Removing a Part of the Photoresist Film on the Upper Surface of the Metal Substrate.

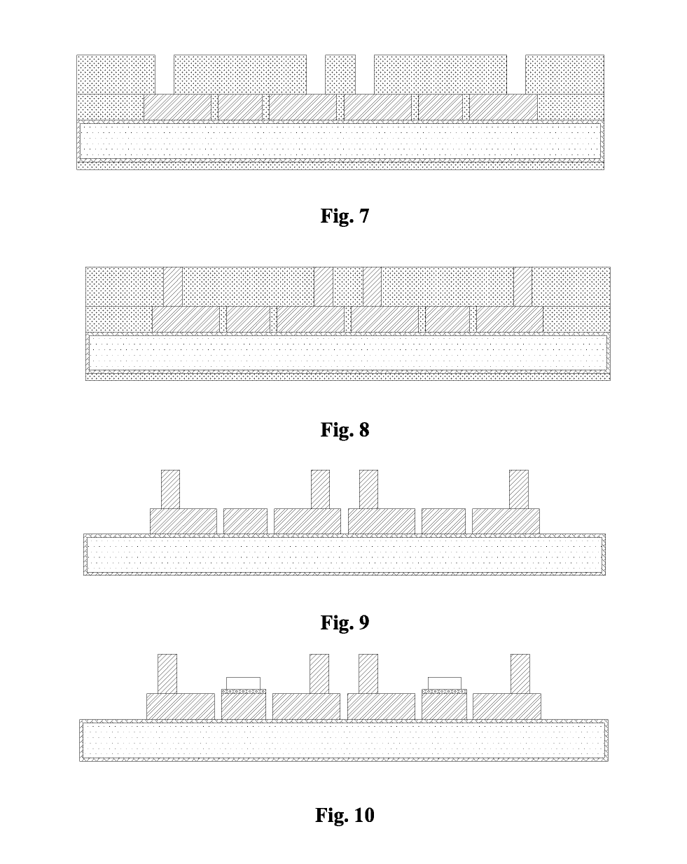

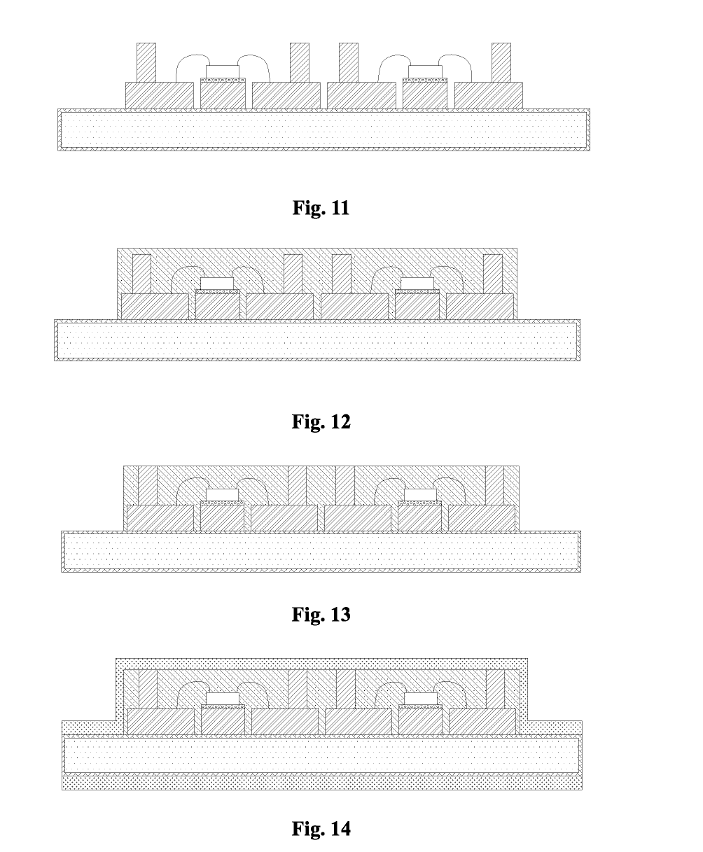

Referring to FIG. 7, the upper surface of the metal substrate applied with the photoresist film in step 6 is exposed and developed in a pattern by an exposure and development device, to remove the part of the photoresist film in the pattern and expose a region of the upper surface of the metal substrate to be plated with conductive pillars.

Step 8, Plating with the Conductive Pillars.

Referring to FIG. 8, the region of the upper surface of the metal substrate, on which the part of the photoresist film has been removed in step 7, is plated with the conductive pillars. The conductive pillar may be made from copper, aluminum, nickel, silver, gold, copper-silver, nickel-gold, nickel-palladium-gold, metal material which may conduct the electricity or the like. The plating may be electrolytic plating, and may achieved by chemical deposition may.

Step 9, Removing the Photoresist Film.

Referring FIG. 9, the photoresist film on the surface of the metal substrate is removed. The step for removing the photoresist film includes: softening the photoresist film with a chemical regent or cleaning the surface of the metal substrate with high pressure water.

Step 10, Bonding Dies.

Referring to 10, a conductive or non-conductive adhesive material is applied on upper surfaces of the pads formed in step 5 to bond first dies.

Step 11, Bonding Metal Wires.

Referring to 11, the metal wires are bonded between an upper surface of the first die and the pins formed in step 5.

Step 12, Molding with an Epoxy Resin.

Referring to FIG. 12, the upper surface of the metal substrate bonded with the die and the wires is molded with the epoxy resin to protect the upper surface of the metal substrate. The epoxy resin material may be selected to be an epoxy with or without filler depending on product characteristic.

Step 13, Grinding a Surface of the Epoxy Resin.

Referring to FIG. 13, the surface of the epoxy resin is ground after the epoxy resin is molded in step 12.

Step 14, Applying a Photoresist Film.

Referring to FIG. 14, the photoresist film for exposing and developing is applied on the upper surface and the lower surface of the metal substrate after the surface of the epoxy resin is ground in step 13.

Step 15, Removing a Part of the Photoresist Film on the Lower Surface of the Metal Substrate.

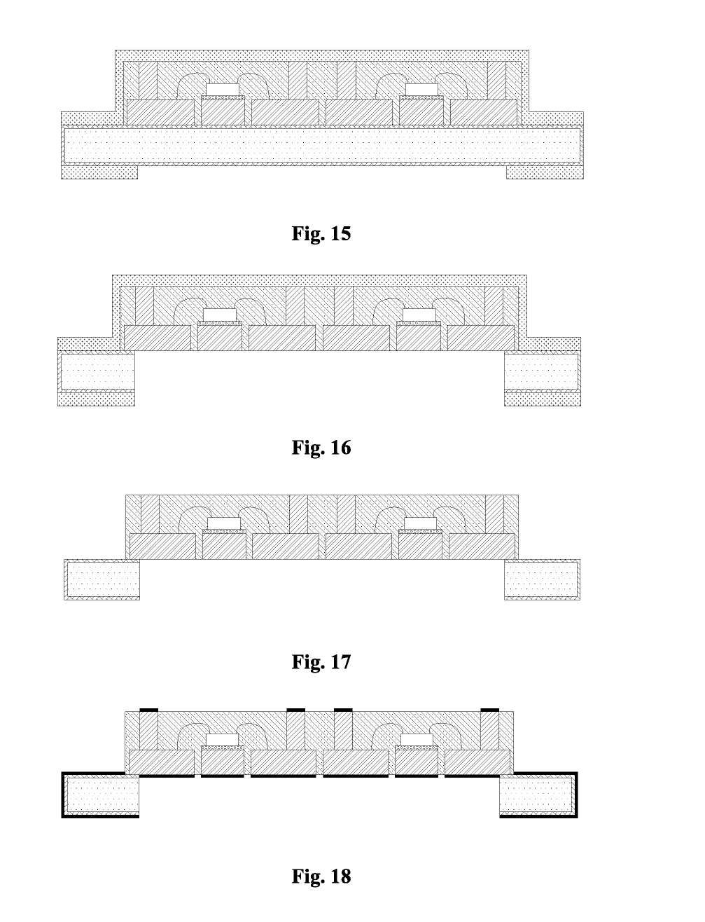

Referring to FIG. 15, the lower surface of the metal substrate applied with the photoresist film in step 14 is exposed and developed in a pattern by an exposure and development device to remove the part of the photoresist film in the pattern and expose a region of the lower surface of the metal substrate to be etched.

Step 16, Etching.

Referring to FIG. 16, a chemical etching is performed in the region of the lower surface of the metal substrate, on which the part of the photoresist film is removed in step 15. The etching method may be an etching process using copper chloride or ferric chloride.

Step 17, Removing the Photoresist Film.

Referring to FIG. 17, the photoresist film on the surface of the metal substrate is removed, and a step of removing the photoresist film includes softening the photoresist film with a chemical regent or cleaning the surface of the metal substrate with high pressure water.

Step 18, Plating with an Anti-Oxidizing Metal Layer or Coating with an Antioxidant (Organic Solderability Preservative, OSP).

Referring to FIG. 18, the exposed surface of the metal substrate, on which the photoresist film has been removed in step 17, is plated with the anti-oxidizing metal layer, such as gold, nickel-gold, nickel-palladium-gold or tin, or is coated with the antioxidant (OSP).

Step 19, Flipping Chips.

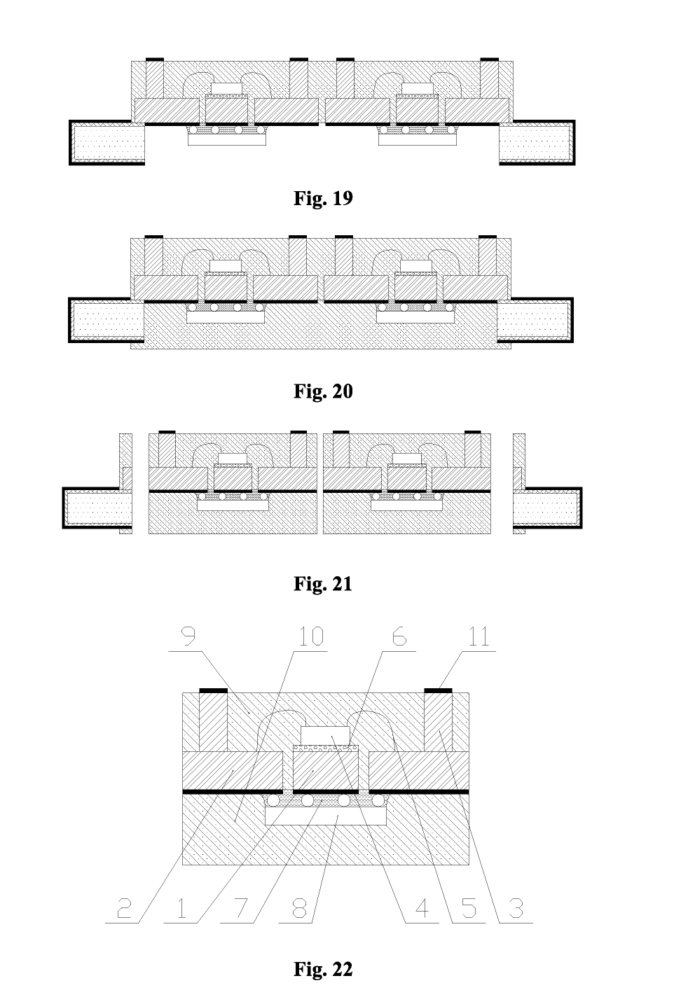

Referring to FIG. 19, multiple second dies are flipped on a lower surface of the pads and the pins plated with the anti-oxidizing metal layer or coated with the antioxidant, by filling gaps between metal balls, between the die and the pad, and between the pads with an underfill.

Step 20, Molding with an Epoxy Resin.

Referring to FIG. 20, the lower surface of the metal substrate bonded with the dies is molded with the epoxy resin to protect the lower surface of the metal substrate. The epoxy resin material may be an epoxy with or without filler depending on the product characteristic.

Step 21, Package Sawing to Form a Finished Product.

Referring to FIG. 21, a semi-finished product is sawed after the epoxy resin is molded in step 20, and molded body modules of the metal wiring substrate, which are integrated initially in an array aggregate and contain chips, are sawed to be separated from one another, to form the finished product of the first-packaged and later-etched three-dimensional flip-chip system-in-package package structure.

### Second Embodiment

### Single-Layer Wiring, Single Flip-Chip, and Lap Lead (2)

Referring to FIG. 47, a first-packaged and later-etched three-dimensional flip-chip system-in-package structure is provided in the present disclosure, which includes: a pad 1; a pin 2; a conductive pillar 3 provided on a upper surface of the pin 2; a first die 4 flipped on an upper surface of the pad 1 by a conductive or non-conductive adhesive material 6; a first metal wire 5 for connecting an upper surface of the first die 4 to the upper surface of the pin 2; a first molding material or epoxy resin 9 for encapsulating with regions of the upper surface of the pad 1 and a pin 2, and a peripheral region of the conductive pillar 3, the first die 4 and the first metal wire 5, with a top of the first molding material or epoxy resin 9 being flush with a top of the conductive pillar 3; a second die 8 flipped on the top of the conductive pillar 3 via first metal balls 17; and a second molding material or epoxy resin 10 for encapsulating with a top region of the conductive pillar 3 and a peripheral region of the second die 8; high conductivity metal layers 12 provided on lower surfaces of the pad 1 and the pin 2; a solder mask or sensitive non-conductive adhesive material 13 filled between the high conductivity metal layers 12; and a anti-oxidation layer 11 provided on surfaces of the high conductivity metal layers 12 exposed from the solder mask or sensitive non-conductive adhesive material 13.

The second embodiment differs from the first embodiment in that, a conductive pillar 3 according to the second embodiment is used actually as an inner lead, and the second molding process is performed on the upper surface of the metal substrate. However, in the first embodiment, the conductive pillar 3 is used actually as an outer lead, and the second molding process is performed on the lower surface of the metal substrate.

The processing method of a first-packaged and later-etched three-dimensional flip-chip system-in-package structure includes the following steps 1 to 24.

Step 1, Preparing a Metal Substrate.

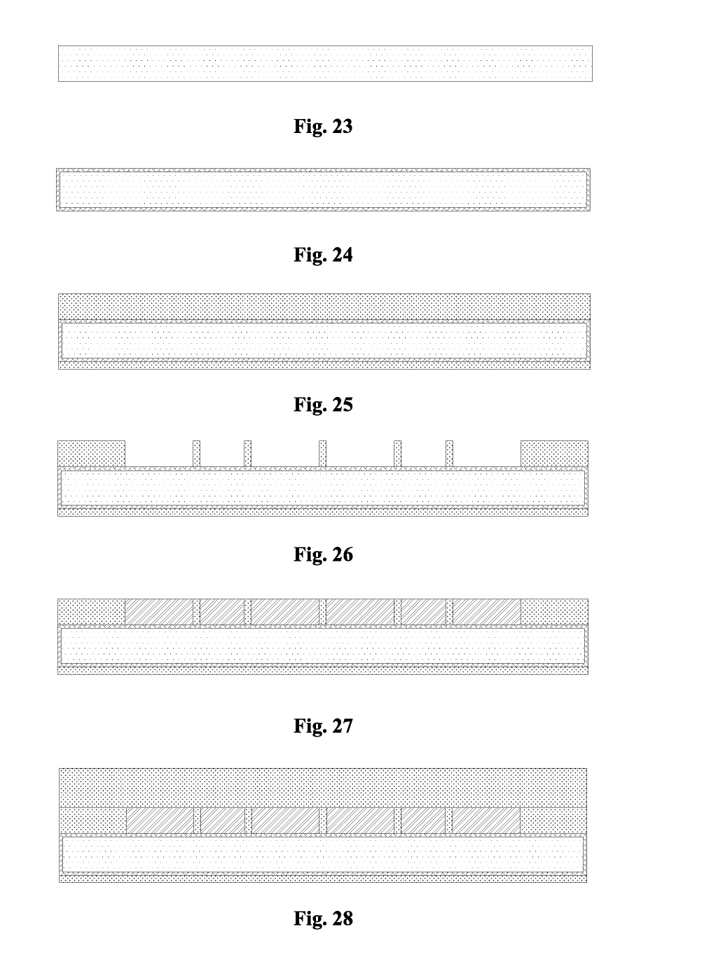

Referring to FIG. 23, the metal substrate of a suitable thickness is prepared. The metal substrate may be made from copper material, iron material, galvanized material, stainless steel, aluminum material or metal material which may conduct the electricity. The thickness of the metal substrate may be selected according to the product characteristic.

Step 2, Pre-Plating Surfaces of the Metal Substrate with a Copper Material.

Referring to FIG. 24, the surfaces of the metal substrate are pre-plated with a layer of copper material. The copper layer has a thickness of 2 μm to 10 μm, which may also be thinned or thickened according to the function requirement. The plating may be electrolytic plating, and may also be achieved by chemical deposition.

Step 3, Applying a Photoresist Film.

Referring to FIG. 25, for manufacturing a metal wiring pattern on the metal substrate later, the photoresist film for exposing and developing is applied on an upper surface and a lower surface of the metal substrate pre-plated with the copper material in step 2. The photoresist film may be a dry photoresist film or a wet photoresist film.

Step 4, Removing a Part of the Photoresist Film on the Upper Surface of the Metal Substrate.

Referring to FIG. 26, the upper surface of the metal substrate applied with the photoresist film in step 3 is exposed and developed in a pattern by an exposure and development device, and the part of the photoresist film in the pattern is removed to expose a region of the upper surface of the metal substrate to be plated with a metal wiring layer.

Step 5, Plating with the Metal Wiring Layer.

Referring to FIG. 27, the region of the upper surface of the metal substrate, on which the part of the photoresist film is removed in step 4, is plated with the metal wiring layer to form pads and pins on the upper surface of the metal substrate. The metal wiring layer may be made from copper, aluminum, nickel, silver, gold, copper-silver, nickel-gold, nickel-palladium-gold, metal material which may conduct the electricity or the like. The metal wiring layer has a thickness of 5 μm to 20 μm. The material for plating may be selected depending on an actual application. The plated thickness may be changed according to the product characteristic. The plating may be electrolytic plating or may also be achieved by the chemical deposition.

Step 6, Applying a Photoresist Film.

Referring to FIG. 28, for manufacturing conductive pillars later, the photoresist film for exposing and developing is applied on the upper surface of the metal substrate plated with the metal wiring layer in step 5. The photoresist film may be a dry photoresist film or a wet photoresist film.

Step 7, Removing a Part of the Photoresist Film on the Upper Surface of the Metal Substrate.

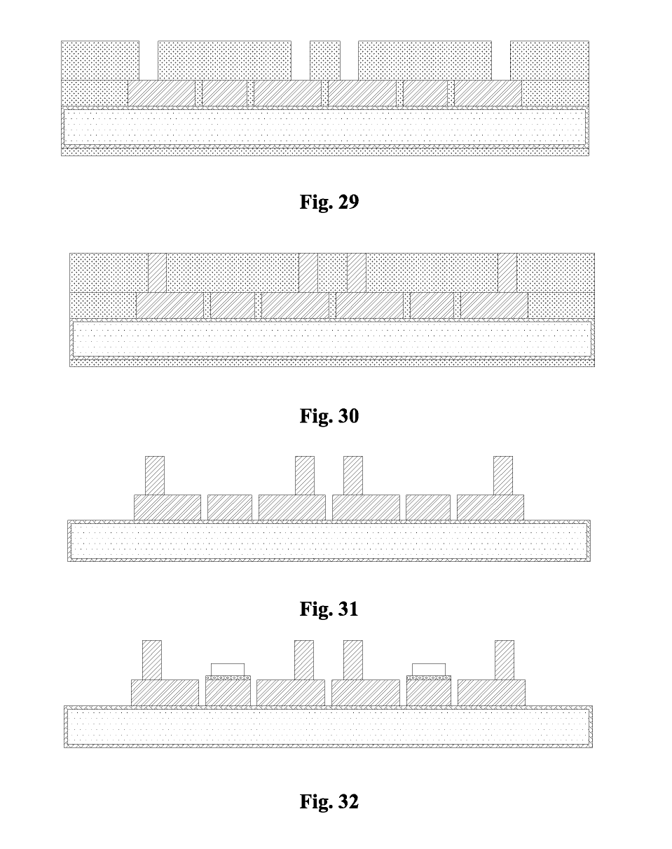

Referring to FIG. 29, the upper surface of the metal substrate applied with the photoresist film in step 6 is exposed and developed in a pattern by an exposure and development device to remove the part of the photoresist film in the pattern and expose a region of the upper surface of the metal substrate to be plated with conductive pillars.

Step 8, Plating with the Conductive Pillars.

Referring to FIG. 30, the region of the upper surface of the metal substrate, on which the part of the photoresist film is removed in step 7, is plated with the conductive pillars. The conductive pillar may be made from copper, aluminum, nickel, silver, gold, copper-silver, nickel-gold, nickel-palladium-gold, metal material which may conduct the electricity or the like. The plating may be electrolytic plating, and may also be achieved by chemical deposition.

Step 9, Removing the Photoresist Film.

Referring to FIG. 31, the photoresist film on the surface of the metal substrate is removed. The step for removing the photoresist film includes: softening the photoresist film with a chemical regent or cleaning the surface of the metal substrate with high pressure water.

Step 10, Bonding Dies,

Referring to FIG. 32, a conductive or non-conductive adhesive material is applied on upper surfaces of the pads formed in step 5 to bond first dies.

Step 11, Bonding Metal Wires.

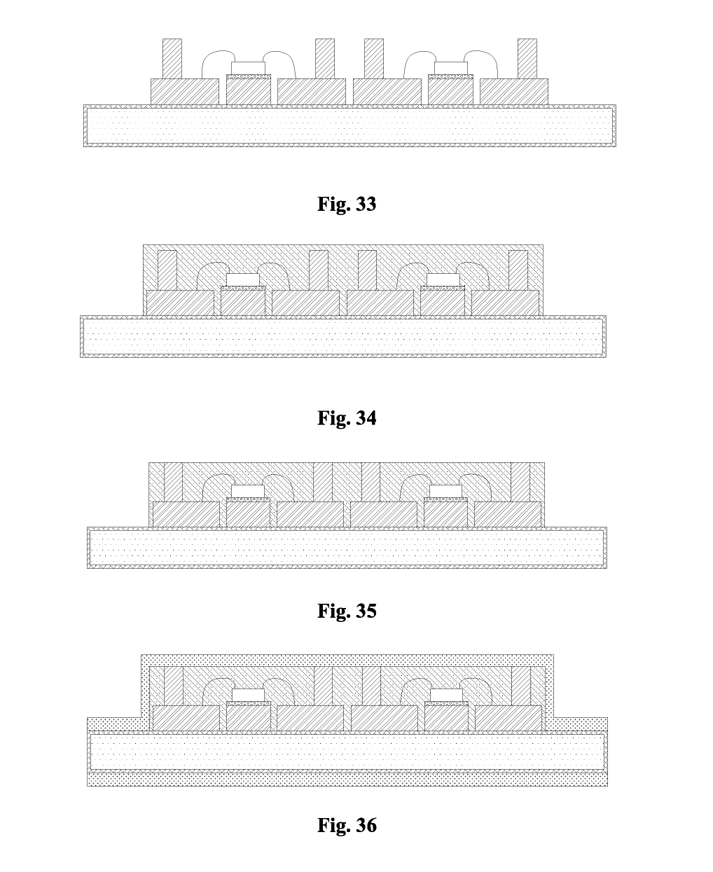

Referring to FIG. 33, the metal wire is bonded between an upper surface of the first die and the pin formed in step 5.

Step 12, Molding with an Epoxy Resin.

Referring to FIG. 34, the upper surface of the metal substrate bonded with the die and the metal wires is molded with the epoxy resin to protect the upper surface of the metal substrate. The epoxy resin material may be an epoxy with or without filler depending on the product characteristic.

Step 13, Grinding a Surface of the Epoxy Resin.

Referring to FIG. 35, the surface of the epoxy resin is ground after the epoxy resin is molded in step 12.

Step 14, Applying a Photoresist Film.

Referring to FIG. 36, the photoresist film for exposing and developing is applied on the upper surface and the lower surface of the metal substrate after the surface of the epoxy resin is ground in step 13.

Step 15, Removing a Part of the Photoresist Film on the Lower Surface of the Metal Substrate.

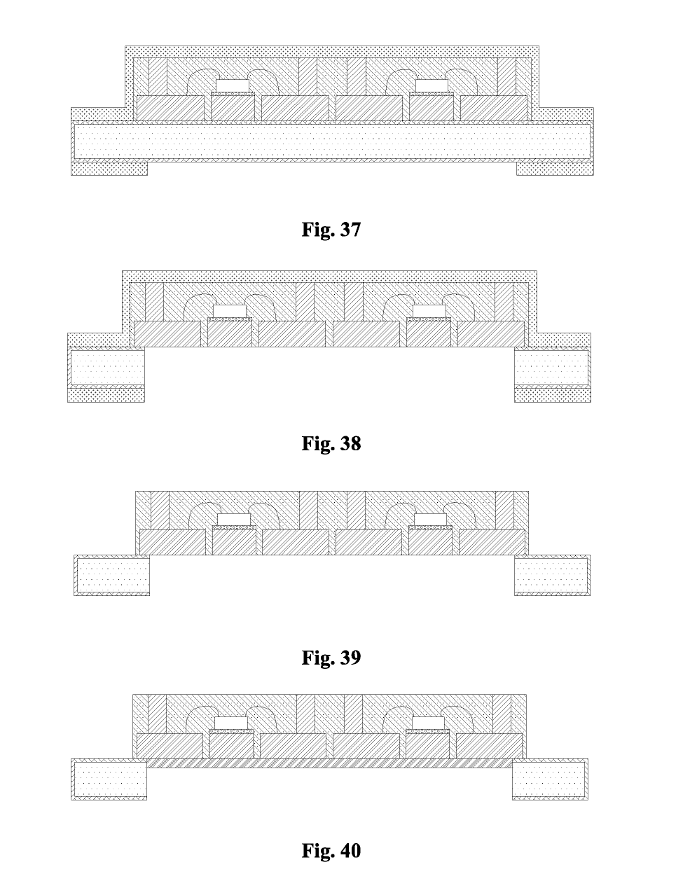

Referring to FIG. 37, the lower surface of the metal substrate applied with the photoresist film in step 14 is exposed and developed in a pattern by an exposure and development device to remove the part of the photoresist film in the pattern and expose a region of the lower surface of the metal substrate to be etched.

Step 16, Etching.

Referring to FIG. 38, a chemical etching is performed on the region of the lower surface of the metal substrate, on which the part of the photoresist film is removed in step 15. The method for etching may be an etching process using copper chloride or ferric chloride.

Step 17, Removing the Photoresist Film.

Referring to FIG. 39, the photoresist film on the surface of the metal substrate is removed by softening the photoresist film with a chemical regent or cleaning the surface of the metal substrate with high pressure water.

Step 18, Coating the Lower Surface of the Metal Substrate with a Solder Mask.

Referring to FIG. 40, the lower surface of the metal substrate is coated with the solder mask after the photoresist film has been removed in step 17.

Step 19, Exposing and Developing to Form a Window.

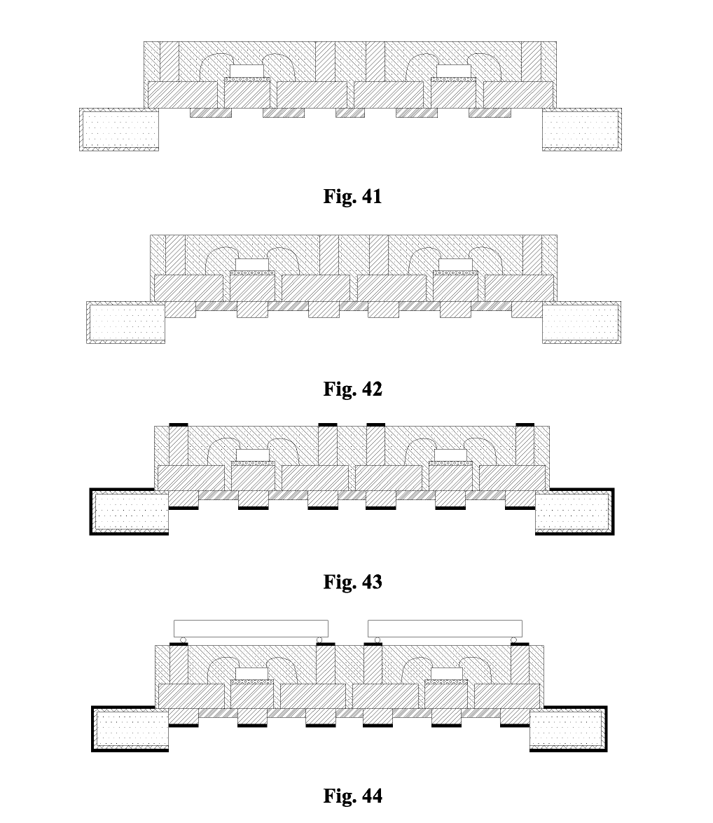

Referring to FIG. 41, the solder mask on the lower surface of the metal substrate is exposed and developed by an exposure and development device to form the window and expose a region of the lower surface of the metal substrate to be plated with a high conductivity metal layer.

Step 20, Plating with the High Conductivity Metal Layer.

Referring to FIG. 42, a region of the window of the solder mask in step 19 on the lower surface of the metal substrate is plated with the high conductivity metal layer. The plating may be electrolytic plating, and may also be achieved by chemical deposition.

Step 21, Plating with an Anti-Oxidizing Metal Layer or Coating with an Antioxidant (OSP).

Referring to FIG. 43, the exposed surface of the metal substrate is plated with the anti-oxidizing metal layer, such as, gold, nickel-gold, nickel-palladium-gold or tin; or is coated with the antioxidant (OSP).

Step 22, Flipping Chips.

Referring to FIG. 44, second dies are flipped, via second metal balls, on tops of the conductive pillars plated with the anti-oxidizing metal layer or coated with the antioxidant in step 21, and an underfill may be implanted below the flipped second dies to fill gaps between metal balls, and between the chip and a molding material.

Step 23, Molding with an Epoxy Resin.

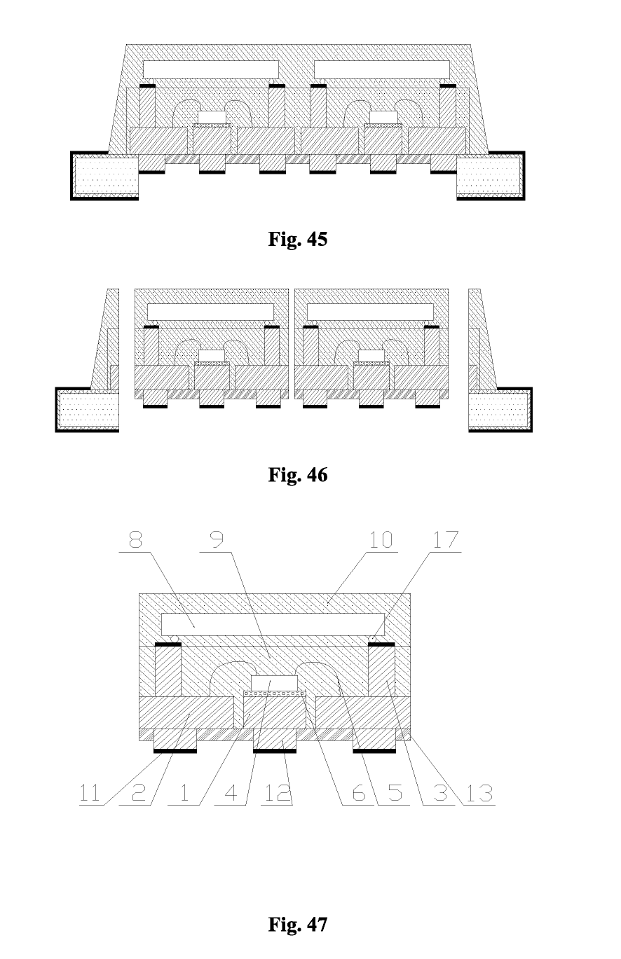

Referring to FIG. 45, the surface of epoxy resin bonded with the die is molded with the epoxy resin again. The epoxy resin material may be an epoxy with or without filler according to the product characteristic.

Step 24, Package Sawing to Form a Finished Product.

Referring to FIG. 46, a semi-finished product is sawed after the epoxy resin is molded in step 23, and molded body modules of the metal wiring substrate, which are integrated initially in a array aggregate and contain chips, are sawed to be separated from one another, to form the finished product of the first-packaged and later-etched three-dimensional flip-chip system-in-package structure.

### Third Embodiment

### Multiple-Layer Wiring, One Flip-Chip, Lap Lead

Referring to FIG. 93, a first-packaged and later-etched three-dimensional flip-chip system-in-package structure is provided in the present disclosure, which includes: a pad 1; a pin 2; a conductive pillar 3 disposed on an upper surface of the pin 2; a first die 4 flipped on a upper surface of the pad 1 by a conductive or non-conductive adhesive material 6; a first metal wire 5 for connecting an upper surface of the first die 4 to the upper surface of the pin 2; a first molding material or epoxy resin 9 for encapsulating with regions of the upper surfaces of the pad 1 and the pin 2, and a peripheral region of the conductive pillar 3, the first die 4 and the first metal wire 5, with the top of the first molding material or epoxy resin 9 being flush with a top of the conductive pillar 3; an anti-oxidation layer 11 provided on a surface of the conductive pillar 3 exposed from the first molding material or epoxy resin 9; a second die 8 flipped on lower surfaces of the pad 1 and the pin 2 by an underfill 7; and a second molding material or epoxy resin 10 for encapsulating with regions of the lower surfaces of the pad 1 and the pin 2 and a peripheral region of the second die 8.

The third embodiment differs from the first embodiment in that, a pad 1 and a pin 2 are both formed of multiple metal wiring layers which are connected with each other via a conductive pillar.

The processing method for first-packaged and later-etched a three-dimensional flip-chip system-in-package structure includes the following steps 1 to 45.

Step 1, Preparing a Metal Substrate.

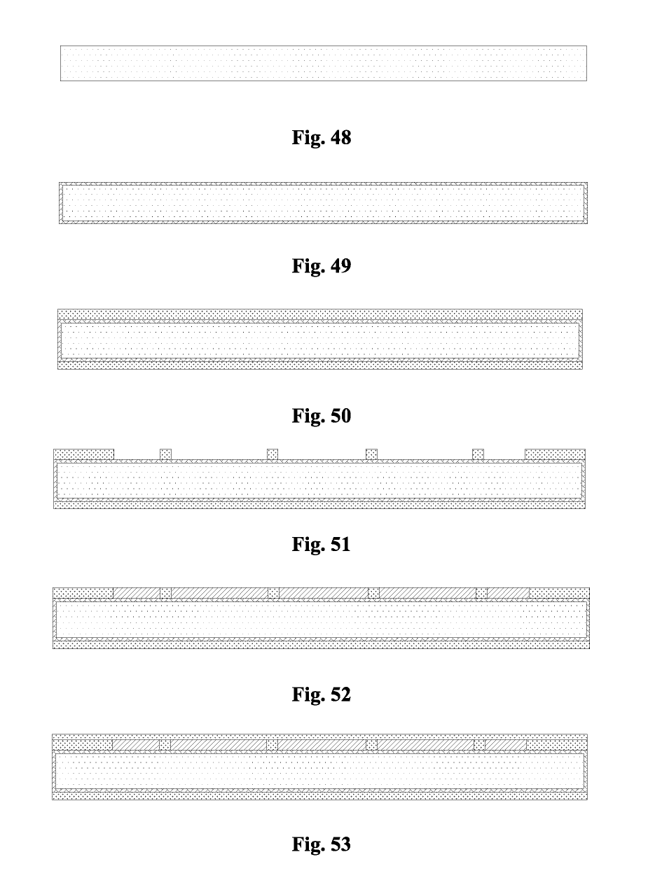

Referring to FIG. 48, the metal substrate of a suitable thickness is prepared. The metal substrate may be made from copper material, iron material, galvanized material, stainless steel, aluminum material, or metal or nonmetal material which may conduct the electricity. The thickness of the metal substrate may be selected according to the product characteristic.

Step 2, Pre-Plating Surfaces of the Metal Substrate with a Copper Material.

Referring to FIG. 49, the surfaces of the metal substrate are pre-plated with a layer of copper material. The copper layer has a thickness of 2 μm to 10 μm, which may also be thinned or thickened depending on the function requirement. The plating may be electrolytic plating, and may also be adopted by chemical deposition.

Step 3, Applying a Photoresist Film.

Referring to FIG. 50, for manufacturing a metal wiring pattern later, the photoresist film for exposing and developing is applied on an upper surface and a lower surface of the metal substrate pre-plated with the copper material in step 2. The photoresist film may be a dry photoresist film or a wet photoresist film.

Step 4, Removing a Part of the Photoresist Film on the Upper Surface of the Metal Substrate.

Referring to FIG. 51, the upper surface of the metal substrate applied with the photoresist film in step 3 is exposed and developed in a pattern by an exposure and development device to remove the part of the photoresist film in the pattern and expose a region of the upper surface of the metal substrate to be plated with a first metal wiring layer.

Step 5, Plating with the First Metal Wiring Layer.

Referring to FIG. 52, the region of the upper surface of the metal substrate, on which the part of the photoresist film is removed in step 4, is plated with the first metal wiring layer. The first metal wiring layer may be made from copper, aluminum, nickel, silver, gold, copper-silver, nickel-gold, nickel-palladium-gold, or the like. The plating may be electrolytic plating, and may also be achieved by chemical deposition.

Step 6, Applying a Photoresist Film.

Referring to FIG. 53, for manufacturing a metal wiring pattern later, the photoresist film for exposing and developing is applied on the upper surface of the metal substrate plated with the first metal wiring layer in step 5. The photoresist film may be a dry photoresist film or a wet photoresist film.

Step 7, Removing a Part of the Photoresist Film on the Upper Surface of the Metal Substrate.

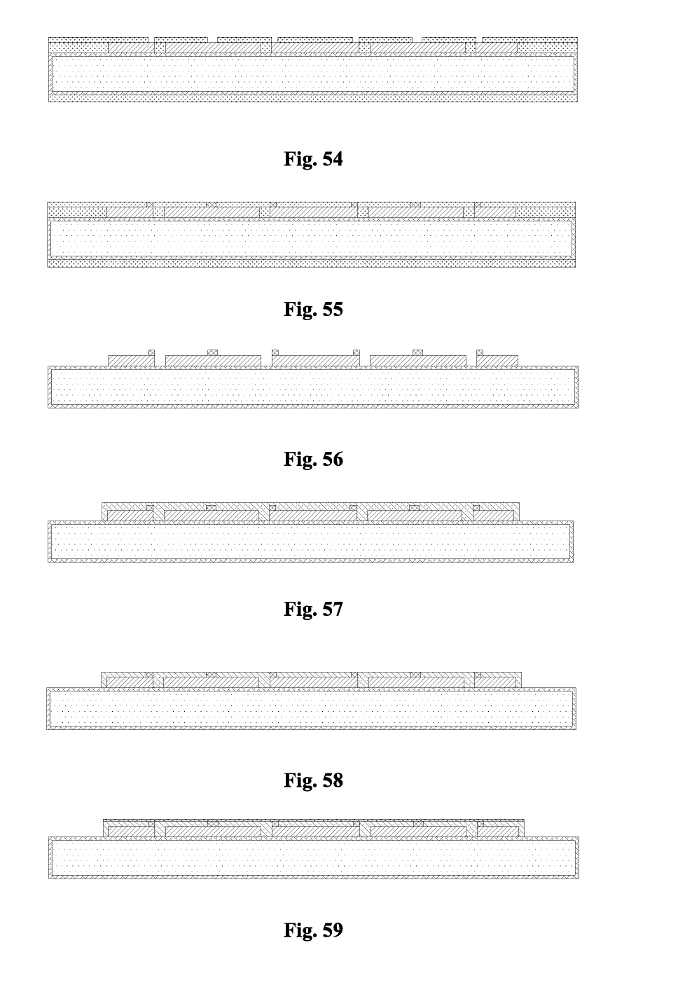

Referring to FIG. 54, the upper surface of the metal substrate applied with the photoresist film in step 6 is exposed and developed in a pattern by an exposure and development device to remove the part of the photoresist film in the pattern and expose a region of the upper surface of the metal substrate to be plated with a second metal wiring layer.

Step 8, Plating with the Second Metal Wiring Layer.

Referring to FIG. 55, the region of the upper surface of the metal substrate, on which the part of the photoresist film is removed in step 7, is plated with the second metal wiring layer. The second metal wiring layer serves as a conductive pillar to connect the first metal wiring layer and a third metal wiring layer. The second metal wiring layer may be made from copper, aluminum, nickel, silver, gold, copper-silver, nickel-gold, nickel-palladium-gold, metal material which may conduct the electricity or the like. The plating may be electrolytic plating, and may also be achieved by the chemical deposition.

Step 9, Removing the Photoresist Film.

Referring to FIG. 56, the photoresist film on the surface of the metal substrate is removed. The steps for removing the photoresist film includes: softening the photoresist film with a chemical regent or cleaning the surface of the metal substrate with high pressure water.

Step 10, Laminating with a Non-Conductive Adhesive Film.

Referring to FIG. 57, a region of the upper surface of the metal substrate (with the wiring layer) is laminated with a layer of the non-conductive adhesive film to insulate the first metal wiring layer from the third metal wiring layer. The step for laminating with the non-conductive adhesive film may include: performing the laminating by a conventional rolling device or in a vacuum environment to prevent air from being trapped during the laminating process. The non-conductive adhesive film is mainly a laminated non-conductive adhesive film made from a thermosetting epoxy resin. The epoxy resin may be an epoxy resin with or without filler according to product characteristic.

Step 11, Grinding a Surface of the Non-Conductive Adhesive Film.

Referring to FIG. 58, after the non-conductive adhesive film is laminated in step 10, the surface of the non-conductive adhesive film is ground to expose the second metal wiring layer, maintain the flatness of the non-conductive adhesive film and the second metal wiring layer, and control the thickness of the non-conductive adhesive film.

Step 12, Performing a Metallization Pretreatment on the Surface of the Non-Conductive Adhesive Film.

Referring to FIG. 59, for providing a conversion intermedium for plating with a metal material later, the metallization pretreatment is performed on the surface of the non-conductive adhesive film to adhere a layer of metallized polymer material onto the surface of the non-conductive adhesive film, or a surface roughening treatment is performed on the surface of the non-conductive adhesive film. The metallized polymer material may be adhered by spraying, plasma oscillation, surface roughening treatment, or the like, and then drying.

Step 13, Applying a Photoresist Film.

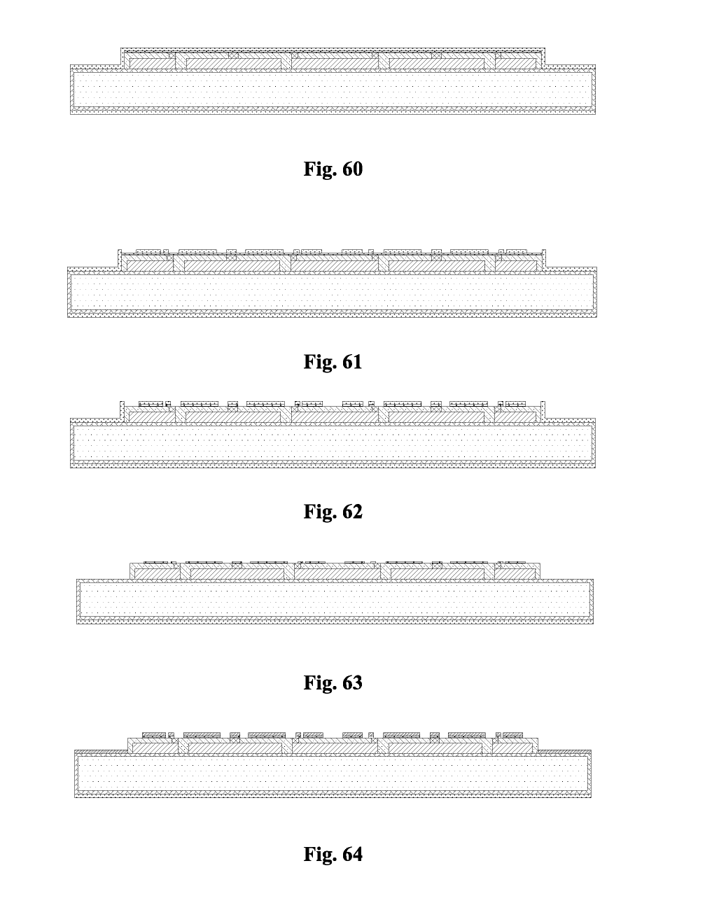

Referring to FIG. 60, for manufacturing a metal wiring pattern later, the photoresist film for exposing and developing is applied on the upper surface and the lower surface of the metal substrate on which the metallization pretreatment is performed in step 12. The photoresist film may be a dry photoresist film or a wet photoresist film.

Step 14, Removing a Part of the Photoresist Film on the Upper Surface of the Metal Substrate.

Referring to FIG. 61, the upper surface of the metal substrate applied with the photoresist film in step 13 is exposed and developed in a pattern by an exposure and development device to remove the part of the photoresist film in the pattern and expose a region of the upper surface of the metal substrate to be etched.

Step 15, Etching.

Referring to FIG. 62, a region of the upper surface of the metal substrate, on which the part of the photoresist film is removed in step 14, is etched to remove a metallization pretreatment region in which the third metal wiring layer is not to be plated. The method for etching may be an etching process using copper chloride or ferric chloride.

Step 16, Removing the Photoresist Film.

Referring to FIG. 63, the photoresist film on the surface of the metal substrate is removed. The steps for removing the photoresist film includes: softening with the photoresist film a chemical regent or cleaning the surface of the metal substrate with high pressure water.

Step 17, Plating with a Third Metal Wiring Layer.

Referring to FIG. 64, a metallization pretreatment region of the upper surface of the metal substrate reserved by the etching in step 15 is plated with the third metal wiring layer. The third metal wiring layer may be made from copper, aluminum, nickel, silver, gold, copper-silver, nickel-gold, nickel-palladium-gold, or the like. The plating may be electrolytic plating, and may also be achieved by the chemical deposition.

Step 18, Applying a Photoresist Film.

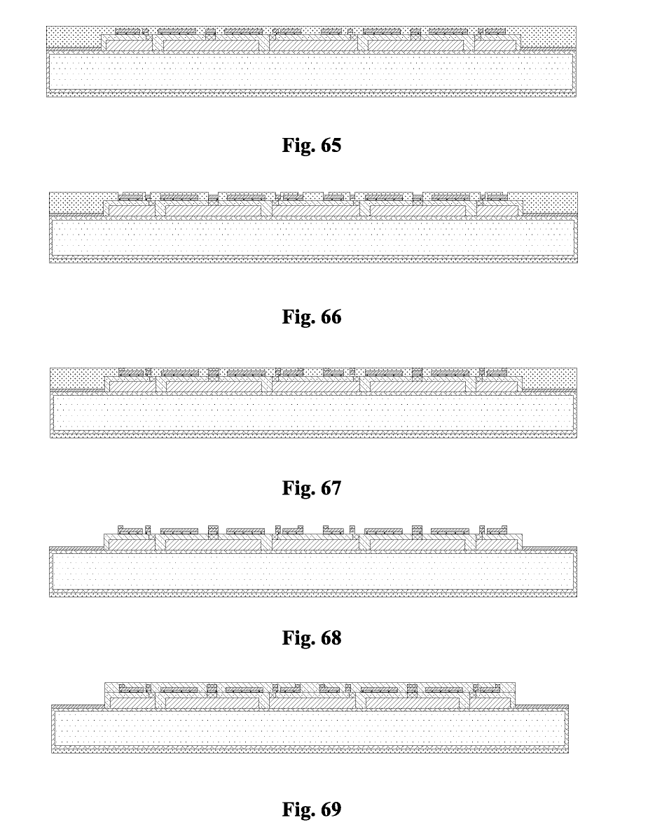

Referring to FIG. 65, for manufacturing a metal wiring pattern later, the photoresist film for exposing and developing is applied on the upper surface of the metal substrate plated with the third metal wiring layer in step 17. The photoresist film may be a dry photoresist film or a wet photoresist film.

Step 19, Removing a Part of the Photoresist Film on the Upper Surface of the Metal Substrate.

Referring to FIG. 66, the upper surface of the metal substrate pasted with the photoresist film in step 18 is exposed and developed in a pattern by an exposure and development device to remove the part of the photoresist film in the pattern and expose a region of the upper surface of the metal substrate to be plated with a fourth metal wiring layer.

Step 20, Plating with the Fourth Metal Wiring Layer.

Referring to FIG. 67, the region of the upper surface of the metal substrate, on which the part of the photoresist film is removed in step 19, is plated with the fourth metal wiring layer. The fourth metal wiring layer serves as a conductive pillar to connect the third metal wiring layer and a fifth metal layer. The fourth metal wiring layer may be made from copper, aluminum, nickel, silver, gold, copper-silver, nickel-gold, nickel-palladium-gold, metal material which may conduct the electricity or the like. The plating may be electrolytic plating, and may be achieved by the chemical deposition.

Step 21, Removing the Photoresist Film.

Referring to FIG. 68, the photoresist film on the surface of the metal substrate is removed. The steps for removing the photoresist film include softening the photoresist film with a chemical regent or cleaning the surface of the metal substrate with high pressure water.

Step 22, Laminating with a Non-Conductive Adhesive Film.

Referring to FIG. 69, the upper surface of the metal substrate (with the wiring layer) is laminated with a layer of the non-conductive adhesive film to insulate the third metal wiring layer from the fifth metal wiring layer. The step for laminating with the non-conductive adhesive film may include: performing the laminating by a conventional rolling device or in a vacuum environment to prevent air from being trapped during the laminating process. The non-conductive adhesive film is mainly a laminated non-conductive adhesive film made from a thermosetting epoxy resin. The epoxy resin may be an epoxy resin with or without filler depending on the product characteristic.

Step 23, Grinding a Surface of the Non-Conductive Adhesive Film.

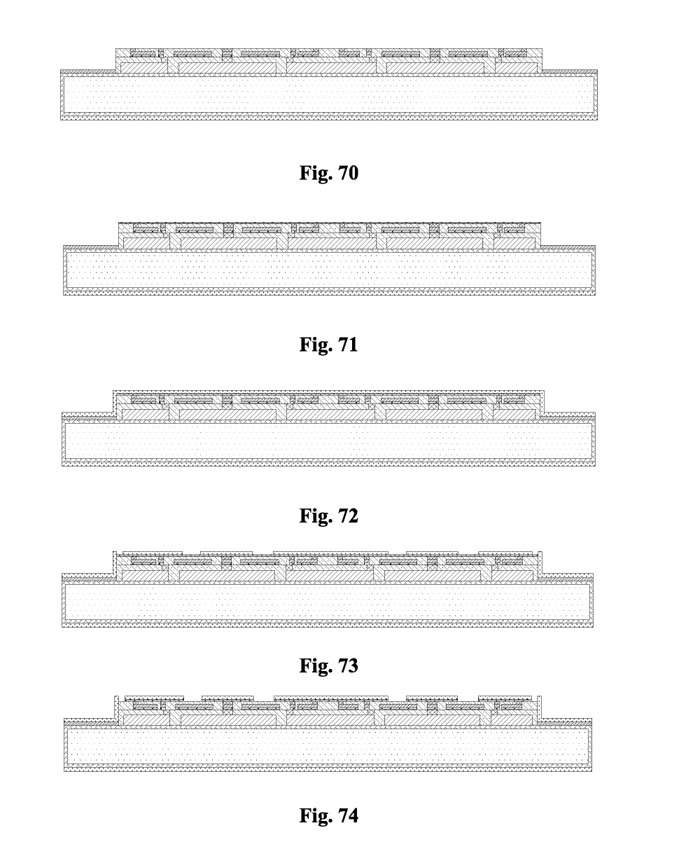

Referring to FIG. 70, after the non-conductive adhesive film is laminated in step 22, the surface of the non-conductive adhesive film is ground to expose the fourth metal wiring layer, maintain the flatness of the non-conductive adhesive film and the fourth metal wiring layer, and control the thickness of the non-conductive adhesive film.

Step 24, Performing a Metallization Pretreatment on the Surface of the Non-Conductive Adhesive Film.

Referring to FIG. 71, for providing a conversion intermedium for plating with a metal material later, the metallization pretreatment is performed on the surface of the non-conductive adhesive film to adhere a layer of metallized polymer material onto the surface of the non-conductive adhesive film, or a roughening treatment is performed on the surface of the non-conductive adhesive film. The metallized polymer material may be adhered by spraying, plasma oscillation, surface roughening treatment, or the like, and then drying.

Step 25, Applying a Photoresist Film.

Referring to FIG. 72, for manufacturing a metal wiring pattern later, the photoresist film for exposing and developing is applied on the upper surface and the lower surface of the metal substrate on which the metallization pretreatment is performed in step 24. The photoresist film may be a dry photoresist film or a wet photoresist film.

Step 26, Removing a Part of the Photoresist Film on the Upper Surface of the Metal Substrate.

Referring to FIG. 73, the upper surface of the metal substrate applied with the photoresist film in step 25 is exposed and developed in a pattern by an exposure and development device to remove the part of the photoresist film in the pattern and expose a region of the upper surface of the metal substrate to be etched.

Step 27, Etching.

Referring to FIG. 73, a region of the upper surface of the metal substrate, on which the part of the photoresist film is removed in step 26, is etched to remove a metallization pretreatment region in which the fifth metal wiring layer is not to be plated. The method for etching may be an etching process using copper chloride or ferric chloride.

Step 28, Removing the Photoresist Film.

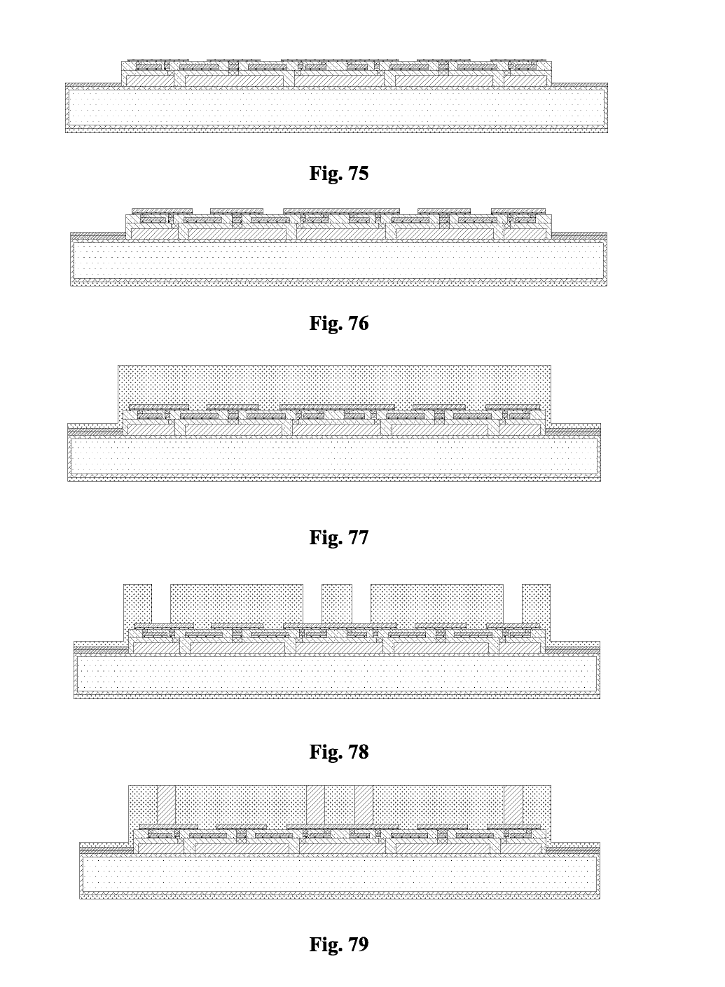

Referring to FIG. 75, the photoresist film on the surface of the metal substrate is removed. The steps for removing the photoresist film include softening the photoresist film with a chemical regent or cleaning the surface of the metal substrate with high pressure water.

Step 29, Plating with a Fifth Metal Wiring Layer.

Referring to FIG. 76, a metallization pretreatment region of the upper surface of the metal substrate reserved by the etching in step 27 is plated with the fifth metal wiring layer to form pads and pins on the upper surface of the metal substrate. The fifth metal wiring layer may be made from copper, aluminum, nickel, silver, gold, copper-silver, nickel-gold, nickel-palladium-gold, or the like. The plating may be electrolytic plating, and may also be achieved by the chemical deposition.

Step 30, Applying with a Photoresist Film.

Referring to FIG. 77, for manufacturing conductive pillars later, the photoresist film for exposing and developing is applied on the upper surface of the metal substrate plated with the fifth metal wiring layer in step 29. The photoresist film may be a dry photoresist film or a wet photoresist film.

Step 31, Removing a Part of the Photoresist Film on the Upper Surface of the Metal Substrate.

Referring to FIG. 78, the upper surface of the metal substrate applied with the photoresist film in step 30 is exposed and developed in a pattern by an exposure and development device to remove the part of the photoresist film in the pattern and expose a region of the upper surface of the metal substrate to be plated with the conductive pillars.

Step 32, Plating with the Conductive Pillars.

Referring to FIG. 79, the region of the upper surface of the metal substrate, on which the part of the photoresist film is removed in step 31, is plated with the conductive pillars. The conductive pillar may be made from copper, aluminum, nickel, silver, gold, copper-silver, nickel-gold, nickel-palladium-gold, metal material which may conduct the electricity or the like. The plating may be electrolytic plating, and may also be achieved by the chemical deposition.

Step 33, Removing the Photoresist Film.

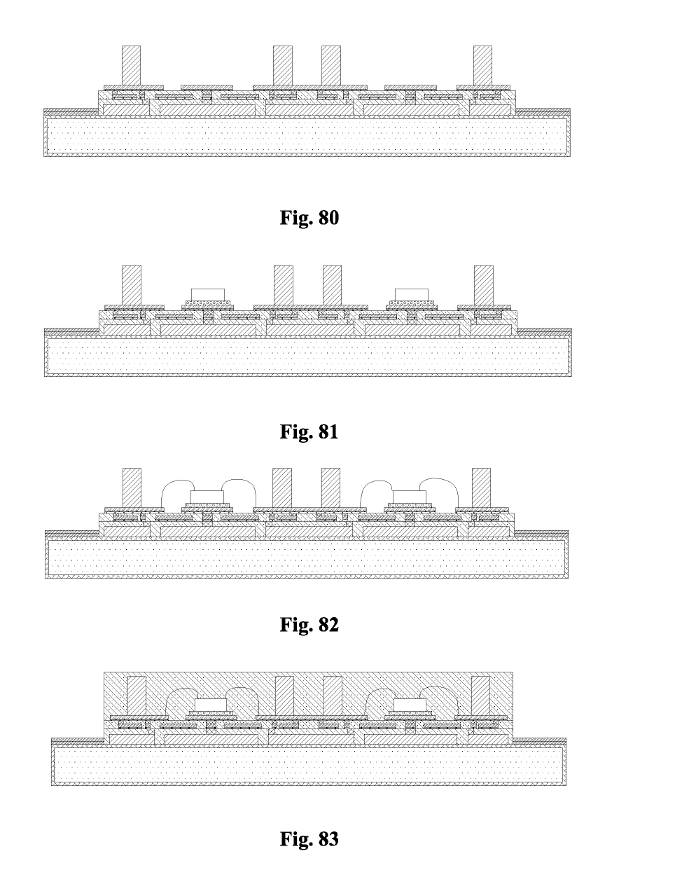

Referring to FIG. 80, the photoresist film on the surface of the metal substrate is removed. The steps for removing the photoresist film include softening the photoresist film with a chemical regent or cleaning the surface of the metal substrate with high pressure water.

Step 34, Bonding Dies.

Referring to FIG. 81, a conductive or non-conductive adhesive material is applied on upper surfaces of the pads formed in step 29 to bond first dies.

Step 35, Bonding Metal Wires.

Referring to FIG. 82, the metal wire is bonded between an upper surface of the first die and the pin formed in step 29.

Step 36, Molding with an Epoxy Resin.

Referring to FIG. 83, the upper surface of the metal substrate bonded with the die and the metal wires is molded with the epoxy resin to protect the upper surface of the metal substrate. The epoxy resin material may be an epoxy resin with or without filler according to the product characteristic.

Step 37, Grinding a Surface of the Epoxy Resin.

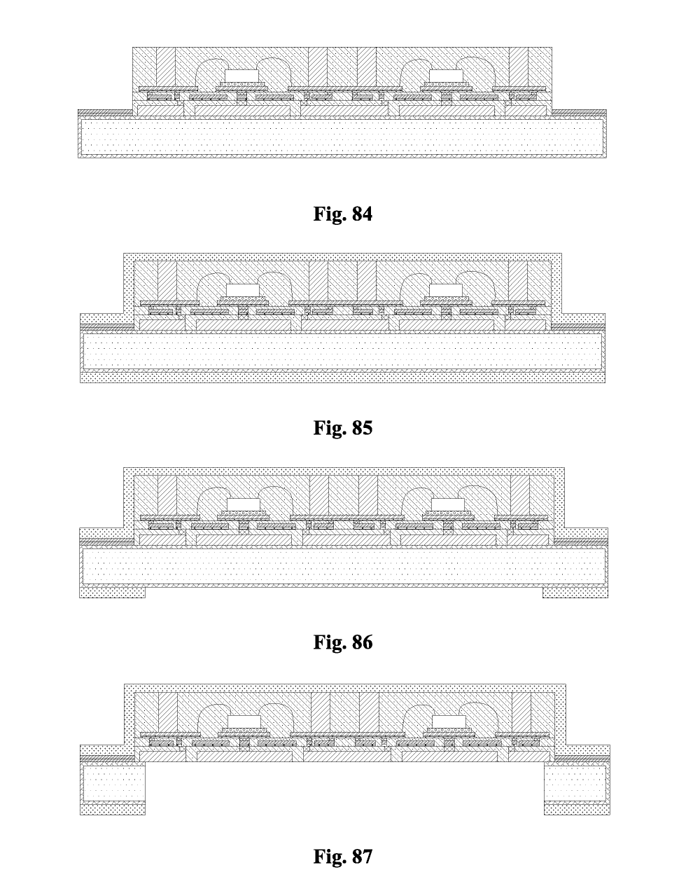

Referring to FIG. 84, the surface of the epoxy resin is ground after the epoxy resin is molded in step 36.

Step 38, Applying a Photoresist Film.

Referring to FIG. 85, the photoresist film for exposing and developing is applied on the upper surface and the lower surface of the metal substrate after the surface of the epoxy resin is ground in step 37.

Step 39, Removing a Part of the Photoresist Film on the Lower Surface of the Metal Substrate.

Referring to FIG. 86, the lower surface of the metal substrate applied with the photoresist film in step 38 is exposed and developed in a pattern by an exposure and development device to remove the part of the photoresist film in the pattern and expose a region of the lower surface of the metal substrate to be etched.

Step 40, Etching.

Referring to FIG. 87, a chemical etching is performed on the region of the lower surface of the metal substrate, on which the part of the photoresist film is removed in step 39. The method for etching may be an etching process using copper chloride or ferric chloride.

Step 41, Removing the Photoresist Film.

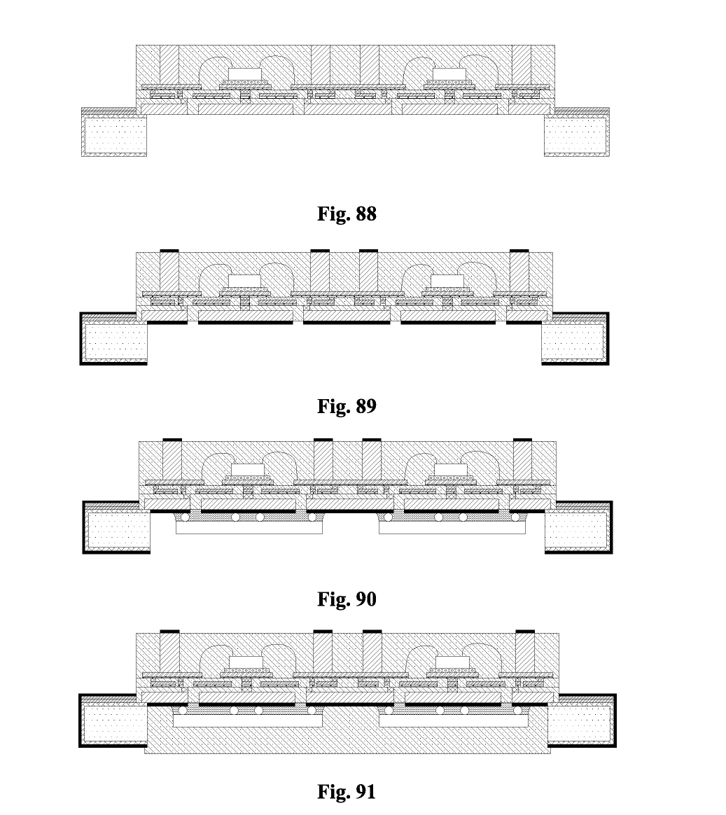

Referring to FIG. 88, the photoresist film on the surface of the metal substrate is removed. The steps for removing the photoresist film includes: softening the photoresist film with a chemical regent or cleaning the surface of the metal substrate with high pressure water.

Step 42, Plating with an Anti-Oxidizing Metal Layer or Coating with an Antioxidant (OSP).

Referring to FIG. 89, the exposed surface of the metal substrate, on which the photoresist film is removed in step 41, is plated with the anti-oxidizing metal layer, such as gold, nickel-gold, nickel-palladium-gold or tin; or is coated with the antioxidant (OSP).

Step 43, Flipping Chips.

Referring to FIG. 90, second dies are flipped on lower surfaces of the pads and the pins plated with the anti-oxidizing metal layer or coated with the antioxidant in step 42, by filling gaps between metal balls, between the die and the pad, and between the pins with an underfill.

Step 44, Molding with an Epoxy Resin.

Referring to FIG. 91, the lower surface of the metal substrate bonded with the die is molded with the epoxy resin to protect the lower surface of the metal substrate. The epoxy resin material may be an epoxy with or without filler according to the product characteristic.

Step 45, Package Sawing to Form a Finished Product.

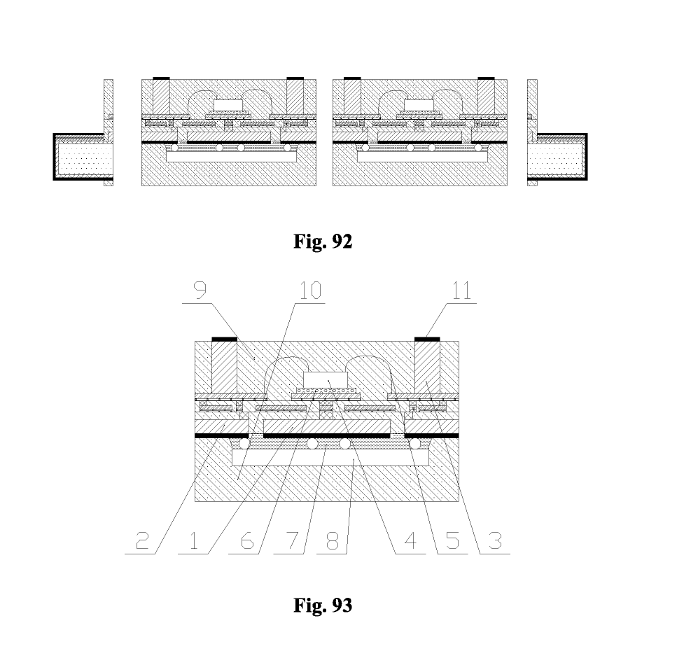

Referring to FIG. 92, a semi-finished product is sawed after the epoxy resin is molded in step 44; and molded body modules of the metal wire substrate, which are integrated initially in array aggregate and contain chips, are sawed to be separated from one another, to form the finished product of the first-packaged and later-etched three-dimensional flip-chip system-in-package structure.

### Fourth Embodiment

### Single Front-Mounted Chip, Lap Lead, and a Passive Device

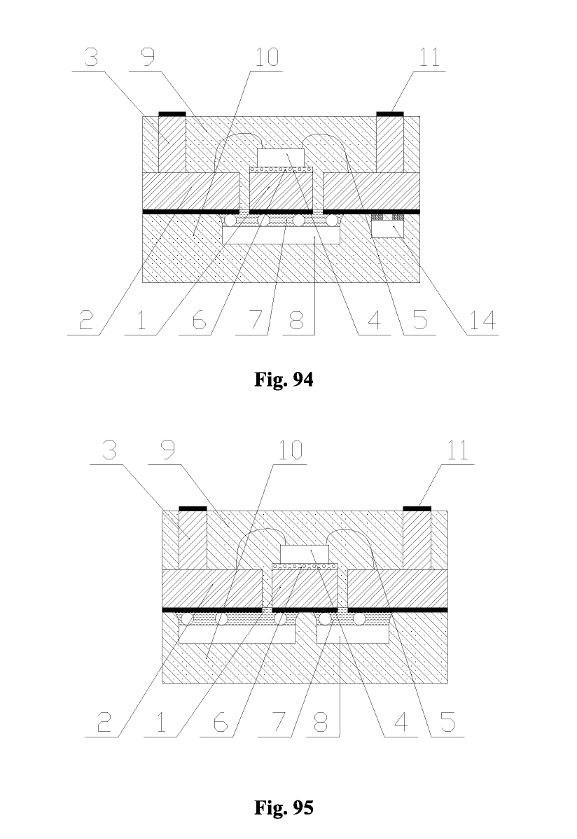

Referring to FIG. 94, the fourth embodiment differs from the first embodiment in that, a passive device 14 is connected across lower surfaces of pins 2.

### Fifth Embodiment

### Tiled Multiple-Chip

Referring to FIG. 95, the fifth embodiment differs from the first embodiment in that, multiple second dies 8 are flipped on the lower surfaces of the pads 1 and the pins 2 by the underfill 7.

### Sixth Embodiment

### Multi-Tier Flip-Chip Stacked Flip-Chip

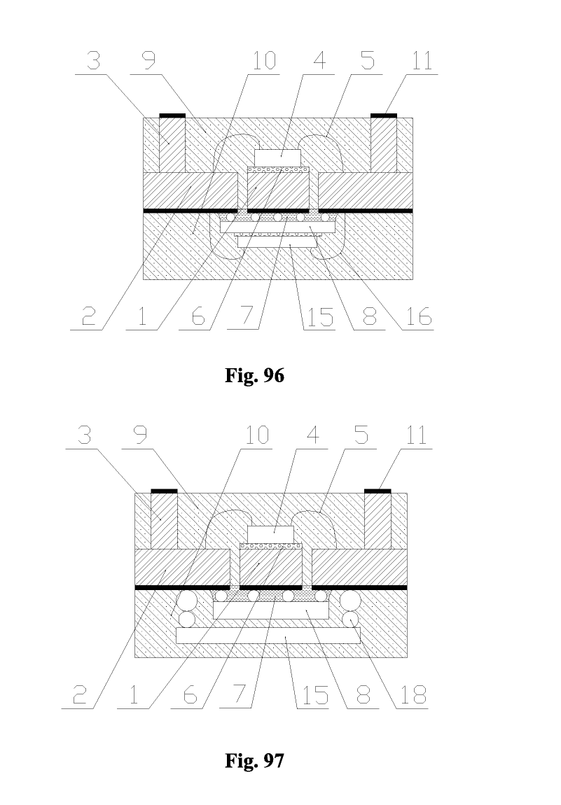

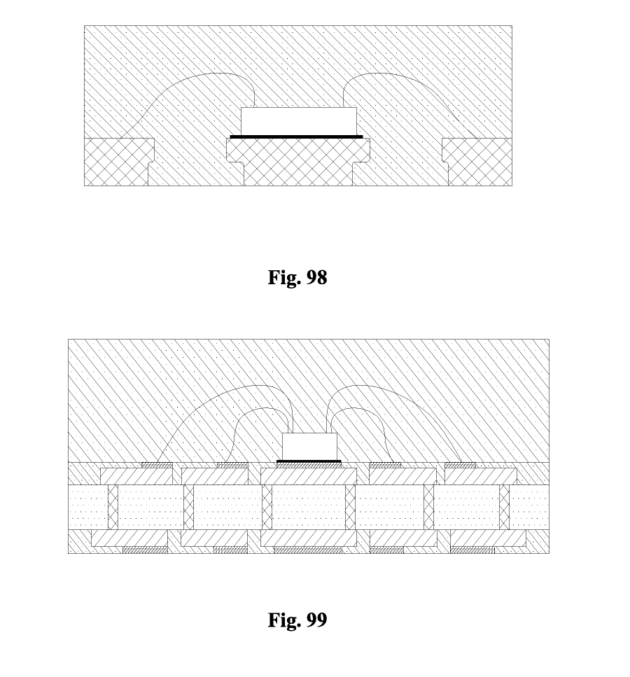

Referring to FIG. 96, the sixth embodiment differs from the first embodiment in that, a third die 15 is front-mounted on the lower surface of the second die 8 by the conductive or non-conductive adhesive material 6, and the third die 15 is connected to the lower surface of the pin 2 via a second metal wire 16.

### Seventh Embodiment

### Multi-Tier Flip-Chip Stacked Flip-Chip

Referring to FIG. 97, the seventh embodiment differs from the first embodiment in that, a third die 15 is flipped on the lower surface of the pin 2 via a second metal ball 18, and the second metal ball 18 and the third die 15 are located within the second molding material or epoxy resin 10.

The third die 15 may be replaced by a passive device 14. The second metal ball 18 and the passive device 14 are located within the second molding material or epoxy resin 10.

What is claimed is:

1. A processing method for a first-packaged and later-etched three-dimensional flip-chip system-in-package structure, comprising:
step 1, preparing a metal substrate;
step 2, pre-plating surfaces of the metal substrate with a copper material,
wherein the surfaces of the metal substrate are pre-plated with a layer of copper material;
step 3, applying a photoresist film,
wherein the photoresist film for exposing and developing is applied on an upper surface and a lower surface of the metal substrate pre-plated with the copper material in step 2;
step 4, removing a part of the photoresist film on the upper surface of the metal substrate,
wherein the upper surface of the metal substrate applied with the photoresist film in step 3 is exposed and developed in a pattern by an exposure and development device to remove the part of the photoresist film in the pattern and expose a region of the upper surface of the metal substrate to be plated with a metal wiring layer;
step 5, plating with the metal wiring layer,
wherein the region of the upper surface of the metal substrate, on which the part of the photoresist film is removed in step 4, is plated with the metal wiring layer to form pads and pins on the upper surface of the metal substrate;
step 6, applying a photoresist film,
wherein the photoresist film for exposing and developing is applied on the upper surface of the metal substrate plated with the metal wiring layer in step 5;
step 7, removing a part of the photoresist film on the upper surface of the metal substrate,
wherein the upper surface of the metal substrate applied with the photoresist film in step 6 is exposed and developed in a pattern by an exposure and development device to remove the part of the photoresist film in the pattern and expose a region of the upper surface of the metal substrate to be plated with conductive pillars;
step 8, plating with the conductive pillars,
wherein the region of the upper surface of the metal substrate, on which the part of the photoresist film is removed in step 7, is plated with the conductive pillars;
step 9, removing the photoresist film,
wherein the photoresist film on the surface of the metal substrate is removed;
step 10, bonding dies,
wherein a conductive or non-conductive adhesive material is applied on upper surfaces of the pads formed in step 5 to bond first dies;
step 11, bonding metal wires,
wherein the metal wire is bonded between an upper surface of the first die and the pin formed in step 5;
step 12, molding with an epoxy resin,
wherein the upper surface of the metal substrate bonded with the dies and the metal wires is molded with the epoxy resin to protect the upper surface of the metal substrate;
step 13, grinding a surface of the epoxy resin,
wherein the surface of the epoxy resin is ground after the epoxy resin is molded in step 12;
step 14, applying a photoresist film,
wherein the photoresist film for exposing and developing is applied on the upper surface and the lower surface of the metal substrate after the surface of the epoxy resin is ground in step 13;
step 15, removing a part of the photoresist film on the lower surface of the metal substrate,
wherein the lower surface of the metal substrate applied with the photoresist film in step 14 is exposed and developed in a pattern by an exposure and development device to remove the part of the photoresist film in the pattern and expose a region of the lower surface of the metal substrate to be etched;
step 16, etching;
wherein a chemical etching is performed in the region of the lower surface of the metal substrate, on which the part of the photoresist film is removed in step 15;
step 17, removing the photoresist film,
wherein the photoresist film on the surface of the metal substrate is removed by softening the photoresist film with a chemical regent or cleaning the surface of the metal substrate with high pressure water;
step 18, plating with an anti-oxidizing metal layer or coating with an antioxidant,
wherein the exposed surface of the metal substrate, on which the photoresist film is removed in step 17, is plated with the anti-oxidizing metal layer or is coated with the antioxidant;
step 19, flipping chips;
wherein second dies are is flipped on lower surfaces of the pads and the pins, which are plated with the anti-oxidizing metal layer or coated with the antioxidant, by filling gaps between metal balls, between the die and the pad, and between the die and the pins with an underfill;
step 20, molding with an epoxy resin,
wherein the lower surface of the metal substrate bonded with the dies is molded with the epoxy resin to protect the lower surface of the metal substrate; and
step 21, package sawing to form a finished product,
wherein a semi-finished product is sawed after the epoxy resin is molded in step 20, and molded body modules of the metal wire substrate, which are integrated initially in an array aggregate and contain dies, are sawed to be separated from one another, to form the finished product of a first-packaged and later-etched three-dimensional flip-chip system-in-package structure.

2. (canceled)

3. A processing method for a first-packaged and later-etched three-dimensional flip-chip system-in-package structure, comprising:
step 1, preparing a metal substrate;
step 2, pre-plating surfaces of the metal substrate with a copper material,
wherein the surfaces of the metal substrate are pre-plated with a layer of copper material;
step 3, applying a photoresist film,
wherein the photoresist film for exposing and developing is applied on an upper surface and a lower surface of the metal substrate;
step 4, removing a part of the photoresist film on the upper surface of the metal substrate,
wherein the upper surface of the metal substrate applied with the photoresist film in step 3 is exposed and developed in a pattern by an exposure and development device to remove the part of the photoresist film in the pattern and expose a region of the upper surface of the metal substrate to be plated with a first metal wiring layer;
step 5, plating with the first metal wiring layer,
wherein the region of the upper surface of the metal substrate, on which the part of the photoresist film is removed in step 4, is plated with the first metal wiring layer;
step 6, applying a photoresist film,
wherein the photoresist film for exposing and developing is applied on the upper surface of the metal substrate plated with the first metal wiring layer in step 5;
step 7, removing a part of the photoresist film on the upper surface of the metal substrate,
wherein the upper surface of the metal substrate applied with the photoresist film in step 6 is exposed and developed in a pattern by an exposure and development device to remove the part of the photoresist film in the pattern and expose a region of the upper surface of the metal substrate to be plated with a second metal wiring layer;
step 8, plating with the second metal wiring layer,
wherein the region of the upper surface of the metal substrate, on which the part of the photoresist film is removed in step 7, is plated with the second metal wiring layer, and the second metal wiring layer serves as a conductive pillar to connect the first metal wiring layer and a third metal wiring layer;
step 9, removing the photoresist film,
wherein the photoresist film on the surface of the metal substrate is removed;
step 10, laminating a non-conductive adhesive film,
wherein a layer of the non-conductive adhesive film is laminated on the upper surface of the metal substrate;
step 11, grinding a surface of the non-conductive adhesive film,
wherein the surface of the non-conductive adhesive film is ground after the non-conductive adhesive film is laminated in step 10;
step 12, performing a metallization pretreatment on the surface of the non-conductive adhesive film,
wherein the metallization pretreatment is performed on the surface of the non-conductive adhesive film to adhere a layer of metallized polymer material onto the surface of the non-conductive adhesive film, or a surface roughening treatment is performed on the surface of the non-conductive adhesive film;
step 13, applying a photoresist film,
wherein the photoresist film for exposing and developing is applied on the upper surface and the lower surface of the metal substrate on which the metallization pretreatment is performed in step 12;
step 14, removing a part of the photoresist film on the upper surface of the metal substrate,
wherein the upper surface of the metal substrate applied with the photoresist film in step 13 is exposed and developed in a pattern by an exposure and development device to remove the part of the photoresist film in the pattern and expose a region of the upper surface of the metal substrate to be etched;
step 15, etching;
wherein the etching is performed on a region of the upper surface of the metal substrate from which the part of the photoresist film is removed in step 14;
step 16, removing the photoresist film,
wherein the photoresist film on the surface of the metal substrate is removed;
step 17, plating with a third metal wiring layer,
wherein a metallization pretreatment region of the upper surface of the metal substrate on reserved by the etching in step 15 is plated with the third metal wiring layer to form pads and pins are correspondingly formed on the upper surface of the metal substrate;
step 18, applying a photoresist film,
wherein the photoresist film for exposing and developing is applied on the upper surface of the metal substrate plated with the third metal wiring layer in step 17;
step 19, removing a part of the photoresist film on the upper surface of the metal substrate,
wherein the upper surface of the metal substrate applied with the photoresist film in step 18 is exposed and developed in a pattern by an exposure and development device to remove the part of the photoresist film in the pattern and expose a region of the upper surface of the metal substrate to be plated with conductive pillars;
step 20, plating with the conductive pillars,
wherein the region of the upper surface of the metal substrate, on which the part of the photoresist film is removed in step 19, is plated with the conductive pillars;
step 21, removing the photoresist film,
wherein the photoresist film on the surface of the metal substrate is removed;
step 22, bonding dies,
wherein a conductive or non-conductive adhesive material is applied on upper surfaces of the pads formed in step 17 to bond first dies;
step 23, bonding metal wires,
wherein the metal wire is bonded between an upper surface of the first die and the pin formed in step 17;
step 24, molding with an epoxy resin,
wherein the upper surface of the metal substrate bonded with the die and the metal wires is molded with the epoxy resin to protect the upper surface of the metal substrate;
step 25, grinding a surface of the epoxy resin,
wherein the surface of the epoxy resin is ground after the epoxy resin is molded in step 24;
step 26, applying a photoresist film,
wherein the photoresist film for exposing and developing is applied on the upper surface and the lower surface of the metal substrate after the surface of the epoxy resin is ground in step 25;
step 27, removing a part of the photoresist film on the lower surface of the metal substrate,
wherein the lower surface of the metal substrate applied with the photoresist film in step 26 is exposed and developed in a pattern by an exposure and development device to remove the part of the photoresist film in the pattern and expose a region of the lower surface of the metal substrate to be etched;
step 28, etching;
wherein a chemical etching is performed on the region of the lower surface of the metal substrate, on which the part of the photoresist film is removed in step 27;
step 29, removing the photoresist film,
wherein the photoresist film on the surface of the metal substrate is removed;
step 30, plating with an anti-oxidizing metal layer or coating with an antioxidant,
wherein the exposed surface of the metal substrate, on which the photoresist film is removed in step 29, is plated with the anti-oxidizing metal layer or is coated with the antioxidant;
step 31, flipping chips;
wherein second dies are flipped on a lower surface of the pad and the pin plated with the anti-oxidizing metal layer or coated with the antioxidant in step 30, by filling gaps between metal balls, between the die and the pad, and between the die and the pin with an underfill;
step 32, molding with an epoxy resin,
wherein the lower surface of the metal substrate bonded with the die is molded with the epoxy resin to protect the lower surface of the metal substrate; and
step 33, package sawing to form a finished product,
wherein a semi-finished product is sawed after the epoxy resin is molded in step 32, and molded body modules of the metal wire substrate, which are integrated initially in array aggregate and contain chips, are sawed to be separated from one another, to form the finished product of a first-packaged and later-etched three-dimensional flip-chip system-in-package structure.

4. The processing method for a first-packaged and later-etched three-dimensional flip-chip system-in-package structure according to claim 3, wherein during step 5 to step 17 are performed, step 8 to step 18 are performed repeatedly.

5. A first-packaged and later-etched three-dimensional flip-chip system-in-package structure, comprising:
a pad (1); a pin (2); a conductive pillar (3) disposed on an upper surface of the pin (2); a first die (4) flipped on an upper surface of the pad (1) by a conductive or non-conductive adhesive material (6); a first metal wire (5) for connecting an upper surface of the first die (4) to the upper surface of the pin (2); a first molding material or epoxy resin (9) for encapsulating with regions of the upper surfaces of the pad (1) and the pin (2), and a peripheral region of the conductive pillar (3), the first die (4) and the first metal wire (5), with a top of the first molding material or epoxy resin (9) being flush with a top of the conductive pillar (3); an anti-oxidation layer (11) provided on a surface of the conductive pillar (3) exposed from the first molding material or epoxy resin (9); a second die (8) flipped on lower surfaces of the pad (1) and the pin (2) by an underfill (7); and a second molding material or epoxy resin (10) for encapsulating with the regions of the lower surfaces of the pad (1) and the pin (2) and a peripheral region of the second die (8).

6. The first-packaged and later-etched three-dimensional flip-chip system-in-package structure according to claim 5, wherein a passive device (14) is connected across the pins (2).

7. The first-packaged and later-etched three-dimensional flip-chip system-in-package structure according to claim 5, wherein a plurality of second dies (8) are flipped on the lower surfaces of the pad (1) and the pin (2) by the underfill (7).

8. The first-packaged and later-etched three-dimensional flip-chip system-in-package structure according to claim 5, wherein a third die (15) is flipped on the lower surface of the second die (8) by the conductive or non-conductive adhesive material (6), and the third die (15) is connected to the lower surface of the pin (2) via a second metal wire (16).

9. The first-packaged and later-etched three-dimensional flip-chip system-in-package structure according to claim 7, wherein a third die (15) is flipped on the lower surface of the second die (8) by the conductive or non-conductive adhesive material (6), and the third die (15) is connected to the lower surface of the pin (2) via a second metal wire (16).

10. The first-packaged and later-etched three-dimensional flip-chip system-in-package structure according to claim 5, wherein a third die (15) is flipped on the lower surface of the pin (2) via a second metal ball (18), and the second metal ball (18) and the third die (15) are located within the second molding material or epoxy resin (10).

11. The first-packaged and later-etched three-dimensional flip-chip system-in-package structure according to claim 7, wherein a third die (15) is flipped on the lower surface of the pin (2) via a second metal ball (18), and the second metal ball (18) and the third die (15) are located within the second molding material or epoxy resin (10).

12. The first-packaged and later-etched three-dimensional flip-chip system-in-package structure according to claim 8, wherein a third die (15) is flipped on the lower surface of the pin (2) via a second metal ball (18), and the second metal ball (18) and the third die (15) are located within the second molding material or epoxy resin (10).

13. The first-packaged and later-etched three-dimensional flip-chip system-in-package structure according to claim 9, wherein a third die (15) is flipped on the lower surface of the pin (2) via a second metal ball (18), and the second metal ball (18) and the third die (15) are located within the second molding material or epoxy resin (10).

14. The first-packaged and later-etched three-dimensional flip-chip system-in-package structure according to claim 10, wherein the third die (15) is replaced by a passive device (14), and the second metal ball (18) and the passive device (14) are located within the second molding material or epoxy resin (10).

15. (canceled)

16. The first-packaged and later-etched three-dimensional flip-chip system-in-package structure according to claim 6, wherein a plurality of second dies (8) are flipped on the lower surfaces of the pad (1) and the pin (2) by the underfill (7).

17. The first-packaged and later-etched three-dimensional flip-chip system-in-package structure according to claim 6, wherein a third die (15) is flipped on the lower surface of the second die (8) by the conductive or non-conductive adhesive material (6), and the third die (15) is connected to the lower surface of the pin (2) via a second metal wire (16).

18. The first-packaged and later-etched three-dimensional flip-chip system-in-package structure according to claim 6, wherein a third die (15) is flipped on the lower surface of the pin (2) via a second metal ball (18), and the second metal ball (18) and the third die (15) are located within the second molding material or epoxy resin (10).
